(19) United States
(12) Patent Application Publication
(10) Pub. No.: US 2024/0265176 A1
(43) Pub. Date: Aug. 8, 2024

(54) APPAREL AND 3D OBJECT PATTERNMAKING SYSTEM AND METHOD

(71) Applicant: Anne Kuehn, Broomfield, CO (US)

(72) Inventor: Anne Kuehn, Broomfield, CO (US)

(21) Appl. No.: 18/637,618

(22) Filed: Apr. 17, 2024

Related U.S. Application Data
(63) Continuation-in-part of application No. 17/879,006, filed on Aug. 2, 2022, now Pat. No. 11,969,041.
(60) Provisional application No. 63/228,559, filed on Aug. 2, 2021.

(51) Int. Cl. G06F 30/27

(52) U.S. Cl. CPC G06F 30/27

(57) ABSTRACT

Apparel and 3D object patternmaking software with selectable base slopers and base 3D object templates for creating digital sewing patterns and 3D object patterns. Body or 3D object measurements are imported from a body scanner or 3D object scanner or received as manual measurements. The base slopers or base 3D object templates are adjusted per user-selected or default conditions based on relationships between the body or 3D object measurements. New conditions and default choices may be added to edit the base sloper or base 3D object template.

### CROSS-REFERENCE TO RELATED APPLICATIONS

This application is a continuation-in-part of U.S. non-provisional application Ser. No. 17/879,006, filed on Aug. 2, 2022, which claims priority to U.S. provisional application No. 63/228,559, filed on Aug. 2, 2021, which applications are incorporated herein by reference.

### FIELD OF THE DISCLOSURE

This disclosure generally relates to a computer implemented system to create digital patterns for apparel or 3D objects using a patternmaking software application that allows a created pattern to be resized and altered as needed in a quick and simple fashion to adjust to various sizes and proportions. The computer implemented method may be used for any type of apparel or object and may simplify the process of creating made-to-measure, bespoke, or other types of clothing and 3D objects. The patternmaking application provides prompts and questions for the user to respond to or select an option, thereby assisting the user in creating a pattern that can be printed and used to create the apparel or object, thus requiring less extensive knowledge and skill in patternmaking to accommodate differences in size and shape among people and objects.

### BACKGROUND

The description provided in this background section should not be assumed to be prior art merely because it is mentioned in or associated with this background section. The background section may include information that describes one or more aspects of the subject technology.

For many centuries, apparel was made by hand based on unique measurements taken by tailors and seamstresses for the individuals that were to wear the custom outfits. Tailors and seamstresses were kept very busy with their work in preparing elaborate and beautiful outfits, in particular, for the wealthier class. There are many historical examples of elaborate, tailored outfits that were not purchased in mass from a store or other location but rather ordered and made to fit a specific individual with a high degree of accuracy and precision in the sizing. Over time, patterns were also used to create different types of clothing and to have a base template to work from, but the patterns were always adjusted by a tailor or seamstress to accommodate the unique measurements and body of the wearer. The tailor or seamstress, then and now, had to have a high amount of skill, knowledge, and understanding of pattern drafting, sewing techniques and methods, and body types to accommodate the pattern to the project at hand and intended wearer or group of wearers.

Over time, countries began developing tables with sizes in which the measurements for each increasing size were proportional with the measurements for the previous sizes. These proportional size systems became more used as ready to wear and commercial clothing brands were developed, but the clothes designed based on the proportional size systems often did not really fit with the actual unique proportions of the wearer.

ASTM (American Society for Testing and Materials) International, or ASTM for short, is an international standards organization that develops and publishes voluntary consensus technical standards and guidelines for a wide range of materials, products, systems, and services. ASTM has developed a set of tables of body measurements for adult males and females ranging from sizes 00-20 that take into consideration body types, such as straight or curvy. The ASTM tables are intended to be used as guidelines and to assist manufacturers in developing patterns and garments that are consistent with the current anthropometric characteristics of the population of interest, and to in turn reduce or minimize consumer confusion and dissatisfaction related to apparel sizing. The reality is that there are many different body shapes. For example, some individuals are straighter (characteristics of teenagers), curvier (like many adult women), or have a higher or lower bust (characteristics of younger and older women, respectively), and so on. For those who have disabilities, such as scoliosis, or other issues where the curve of the back and height of one shoulder as compared to the another are not uniform, standard sizing and categorizing of clothing based on height and weight alone are very lacking.

To add to the difficulty in having clothing properly fit based on a size included on a label alone, there is an overwhelming number of size charts and models used throughout the world with respect to apparel. For example, the United States, Europe, and Asia each have their own catalog sizing that correlates to the average height, weight, and build of the population in these countries. Clothing based on popular clothing catalog sizes have a variety of differences in dimensions and fit. They are not what could be considered “made to measure” or “couture” because they are based on a generalized sizing chart that assumes the same set of dimensions per size (e.g., size 00 to 20 for men or women and the same with children and baby sizes). These sizing charts are based on a proportional system that increases the dimensions for the bust, waist, and hip of a person in an incremental, proportional manner as the size increases.

FIG. 1A is an exemplary table 102 showing how standardized women's catalog sizes in the United States are correlated with average height, weight, bust, waist, and hip measurements. As can be seen in table 102, average bust, waist, and hip measurements increase proportionally as sizes increase. However, table 102 does not consider individual differences, and actual measurements taken by hand are often very different than average measurements per standard size. For example, the waist is often wider than the hips, but in table 102 the hips are always wider than the waist. Mass produced clothing is sometimes made with stretchy material and designed to be somewhat looser to accommodate these differences in body types and sizes. It would be desirable if clothing could be tailored and customized per each individual's unique body type and dimensions without excessive labor costs. It would be further desirable if patterns from which the clothing is based could be produced using an easy-to-use software application.

Existing software applications for creating a pattern for an apparel or clothing item have many deficiencies. For example, GERBER ACCUMARK MADE TO MEASURE is a software application that ties points on the pattern pieces to “points of measurement” (POMs) of the final garment. Pattern pieces are adjusted according to measurement changes. TUKACAD TAILOR EDITION is a software application that works in the same manner. A significant deficiency of such software applications is that they can only handle small changes in measurement from one pattern to another. PATTERNMAKER's MACROGEN is another software application that allows users to calculate and redraw their own patterns, however, it is very complex, does not include pre-built basic patterns, and is only useful for pattern makers who understand complex mathematical functions. None of these existing software applications allow a user to make design edits and then reopen the same file to new parameters for a new size with the same edits. Further, existing software applications do not handle significant changes in body proportion well, in particular in the context of larger sized patterns for larger sized clothing.

Further, existing software applications use a “pattern grading” process that is difficult for the user to calculate and is often inaccurate. Pattern grading is the process of converting a sample size (base size) into smaller or larger sizes. Pattern grading uses a size specification sheet and increases or decreases the size of the original shape of the garment. The grading rule determines the amount by which each POM is made larger or smaller in order to fit a wide range of sizes, with the goal of ensuring good fit and overall balance of shape in a manufactured garment. In software applications that use pattern grading, the user must find which body measurement is closest to the POM at issue and calculate the difference between each size. The user must then calculate how many increments are needed and divide the difference in measurement by the increments. Then, the user must determine how much of each increment is in the X or Y direction and add the X and Y values to the CAD pattern (using for example GERBER ACCUMARK MADE TO MEASURE or another software application). One difficulty with the pattern grading process is a lack of guidelines to assist in determining how much of a measurement difference to accommodate a change in size should be included in each increment.

These problems and deficiencies associated with conventional methods and software applications for creating and editing patterns for clothing and apparel extend as well to creating and editing 3D object patterns for 3D objects. Accordingly, there is a need for an improved apparel and 3D object patternmaking system and software application that addresses these deficiencies.

### SUMMARY

The following summary relates to aspects or embodiments disclosed herein. It is not an extensive overview relating to all contemplated aspects or embodiments, and should not be regarded as identifying key or critical elements of all contemplated aspects or embodiments, or as delineating the scope associated with any particular aspect or embodiment. The following summary has the sole purpose of presenting certain concepts relating to aspects or embodiments disclosed herein in a simplified form to precede the detailed description that follows.

Some aspects of this disclosure are directed to a computer implemented method for producing a digital sewing pattern usable to produce a clothing article or a digital 3D object pattern usable to produce a 3D object. The method comprises receiving a request to open a file for the digital sewing pattern or for the digital 3D object pattern in a patternmaking application, receiving and storing measurements in the patternmaking application relating to the clothing article or relating to the 3D object, and receiving a selection in the patternmaking application for a base sloper or for a base 3D object template.

The method further comprises displaying the base sloper or the base 3D object template in the patternmaking application. The base sloper or the base 3D object template comprise anchor points connected by connecting elements including lines, curves, or other geometric elements. The anchor points correspond to coordinates plottable on an X-Y grid for the base sloper or coordinates plottable on an X-Y-Z grid for the base 3D object template.

The method further comprises displaying conditions in the patternmaking application relating to design details or changes to accommodate unique proportions of the clothing article or of the 3D object. The conditions are displayed as “if/then” statements having true or false fields. The patternmaking application analyzes the measurements and changes an arrangement of one or more of the anchor points or the connecting elements of the base sloper or of the base 3D object template if a condition is met as true or false.

The method further comprises receiving user selections for implementing the conditions from among a first option to apply default design details or changes, a second option to apply different design details or changes, and a third option to apply new conditions with new design details or changes, and updating the conditions according to the user selections.

The method further comprises analyzing, using the patternmaking application, the measurements and the updated conditions and modifying the base sloper or the base 3D object template if needed to produce a finalized sloper corresponding to the digital sewing pattern or a finalized 3D object template corresponding to the digital 3D object pattern, and displaying the digital sewing pattern or the 3D digital object pattern in the patternmaking application.

The method further comprises receiving new measurements relating to the clothing article or relating to the 3D object in the patternmaking application, analyzing, using the patternmaking application, the new measurements and the updated conditions and modifying the finalized sloper or the finalized 3D object template if needed to produce an updated digital sewing pattern or an updated 3D digital object pattern, and displaying the updated digital sewing pattern or the updated 3D digital object pattern in the patternmaking application.

In some implementations, the method further comprises configuring a machine learning trained module to identify errors in the user selections for implementing the conditions, and applying new conditions with new design details or changes to the base sloper or to the base 3D object template based on any errors identified by the machine learning trained module.

In some implementations, when receiving and storing measurements relating to the clothing article or relating to the 3D object, the method further comprises determining whether there are empty measurement fields in the received measurements. If there are empty measurement fields, values are calculated for the empty measurement fields using built in mathematical equations included in the patternmaking application. If the values for the empty measurement fields cannot be calculated, the patternmaking application asks for more data to be provided for the empty measurement fields.

In some implementations, the measurements relating to the digital sewing pattern comprise data received from a body scanner and/or data obtained by manually measuring the clothing article, and the measurements relating to the 3D object comprise data received from a 3D object scanner and/or data obtained from manually measuring the 3D object.

In some implementations, receiving the selection for the base sloper further comprises accessing a base sloper database comprising a plurality of base slopers relating to a plurality of clothing articles, and receiving the selection for the base 3D object template further comprises accessing a 3D object template database comprising a plurality of base 3D object templates relating to a plurality of 3D objects.

In some implementations, the method further comprises displaying the anchor points and the X-Y locations of the anchor points on the X-Y grid for the base sloper, and displaying the anchor points and X-Y-Z locations of the anchor points on the X-Y-Z grid for the base 3D object template.

In some implementations, the method further comprises displaying related measurements and any measurement actions and calculations used to create the X-Y locations of the anchor points for the base sloper, and displaying related measurements and any measurement actions and calculations used to create the X-Y-Z location of the anchor points for the base 3D object template.

Other aspects and advantages of this disclosure will be apparent from the following description, drawings, and appended claims.

### BRIEF DESCRIPTION OF THE DRAWINGS

Embodiments of this disclosure are described below with reference to the drawings. The drawings illustrate select embodiments only and not all possible implementations, and do not limit the scope of this disclosure.

FIG. 1A is an exemplary table showing how standardized women's catalog sizes in the United States are correlated with average height, weight, bust, waist, and hip measurements.

FIG. 1B is a block diagram of an exemplary computing device and additional components for implementing a patternmaking application, in accordance with aspects of this disclosure.

FIG. 2 is a flowchart of an exemplary method of creating digital sewing patterns, in accordance with aspects of this disclosure.

FIG. 3 is a flowchart of an exemplary method for adding measurements to the patternmaking application, in accordance with aspects of this disclosure.

FIG. 4 shows an exemplary base measurement interface of the patternmaking application for receiving base measurements, in accordance with aspects of this disclosure.

FIG. 5 shows an exemplary interface of the patternmaking application for visually displaying different examples of a base sloper for a specific type of clothing article, in accordance with aspects of this disclosure.

FIG. 6 is an exemplary table listing components of a base sloper, including anchor points, connecting lines, curves, and other geometrical elements, in accordance with aspects of this disclosure.

FIG. 7 is a flowchart of an exemplary method for adding anchor points to a base sloper and defining how the anchor points attach to the sloper, in accordance with aspects of this disclosure.

FIG. 8 is an exemplary table indicating whether a line, curve, or other type of geometric element is associated with a seam, a hem or a fold, in accordance with aspects of this disclosure.

FIG. 9 is a flowchart of an exemplary method for defining if/then conditions that may be used to determine a base sloper, according to aspects of this disclosure.

FIGS. 10A and 10B are “before” and “after” views of an exemplary base sloper where a conditional change is made, in accordance with aspects of this disclosure.

FIGS. 11A and 11B are “before” and “after” views of the base sloper of FIGS. 10A-10B where a different conditional change is made, in accordance with aspects of this disclosure.

FIG. 12 shows an exemplary interface of the patternmaking application for selecting options and results for if/then conditional statements, in accordance with aspects of this disclosure.

FIGS. 13A and 13B are front and rear views of an exemplary suit jacket made using a digital sewing pattern produced by the patternmaking application, in accordance with aspects of this disclosure.

FIGS. 14A and 14B are front and rear views of a modified suit jacket made using an updated digital sewing pattern for the suit jacket of FIGS. 13A-13B as modified by the patternmaking application to accommodate an intended wearer that has a narrow waist and a large hip, in accordance with aspects of this disclosure.

FIGS. 15A and 15B are front and rear views of a modified suit jacket made using an updated digital sewing pattern for the suit jacket of FIGS. 13A-13B as modified by the patternmaking application to accommodate an intended wearer that is smaller or of shorter height, in accordance with aspects of this disclosure.

FIGS. 16A and 16B are front and rear views of a modified suit jacket made using an updated digital sewing pattern for the suit jacket of FIGS. 13A-13B as modified by the patternmaking application to accommodate an intended wearer that has wider shoulders, in accordance with aspects of this disclosure.

FIGS. 17A and 17B are front and rear views of a modified suit jacket made using an updated digital sewing pattern for suit jacket 1300 of FIGS. 13A-13B as modified by patternmaking application 128 to accommodate an intended wearer that has one shoulder higher than the other shoulder, in accordance with aspects of this disclosure.

FIG. 18 shows an exemplary conditional results interface of the patternmaking application, in accordance with aspects of this disclosure.

FIG. 19 shows an exemplary double curve sloper for the front hem of the suit jacket of FIGS. 13A-13B, in accordance with aspects of this disclosure.

FIG. 20 shows an exemplary single curve sloper for the front hem of the suit jacket of FIGS. 14A-14B after a code change to the front hem to accommodate an intended wearer that has a narrow waist and a large hip, in accordance with aspects of this disclosure.

FIG. 21 is an exemplary table listing components of the digital sewing pattern or sloper for the suit jacket of FIGS. 13A-13B with codes changed by the apparel patternmaking application to accommodate changes in body proportion, in accordance with aspects of this disclosure.

FIG. 22 is an exemplary X-Y grid used by the patternmaking application to plot locations of anchor points for a base sloper, in accordance with aspects of this disclosure.

FIG. 23 is an exemplary X-Y-Z grid used by the patternmaking application to plot locations of anchor points for a 3D object template or digital 3D object pattern, in accordance with aspects of this disclosure.

FIG. 24 is a flowchart of an exemplary method for creating a digital 3D object pattern using the patternmaking application, in accordance with aspects of this disclosure.

FIG. 25A shows an exemplary 3D object in the form of a shoe stay, according to aspects of this embodiment.

FIG. 25B shows an exemplary 3D view sub-template of the base 3D object template for the shoe stay of FIG. 25A, according to aspects of this disclosure.

FIG. 25C shows an exemplary top view sub-template of the base 3D object template for the shoe stay of FIG. 25A, according to aspects of this disclosure.

FIG. 25D shows an exemplary side view sub-template of the base 3D object template for the shoe stay of FIG. 25A, according to aspects of this disclosure.

FIG. 25E shows an exemplary back view sub-template of the base 3D object template for the shoe stay of FIG. 25A, according to aspects of this disclosure.

FIG. 26A shows an exemplary 3D object in the form of a seat cushion, according to aspects of this embodiment.

FIG. 26B shows an exemplary 3D view sub-template of the base 3D object template for the seat cushion of FIG. 26A, according to aspects of this disclosure.

FIG. 26C shows an exemplary front view sub-template of the base 3D object template for the seat cushion of FIG. 26A, according to aspects of this disclosure.

FIG. 26D shows an exemplary side view sub-template of the base 3D object template for the seat cushion of FIG. 26A, according to aspects of this disclosure.

FIG. 26E shows an exemplary top view sub-template of the base 3D object template for the seat cushion of FIG. 26A, according to aspects of this disclosure.

### DETAILED DESCRIPTION

The preceding and following description is for illustrative purposes only and does not limit the scope of this disclosure. Various aspects and advantages of this disclosure will become apparent from the following detailed description.

While specific details are described below for sake of thorough understanding, many other embodiments may be practiced without these specific details. Well-known circuits, processes, algorithms, structures, and techniques are shown without unnecessary detail in order to avoid obscuring the embodiments. The embodiments described herein are merely exemplary and do not limit the scope or applicability of this disclosure. Rather, this disclosure provides those of skill in the art with an enabling description for implementing the disclosed embodiments. Various changes may be made in the function and arrangement of elements without departing from the spirit and scope of this disclosure.

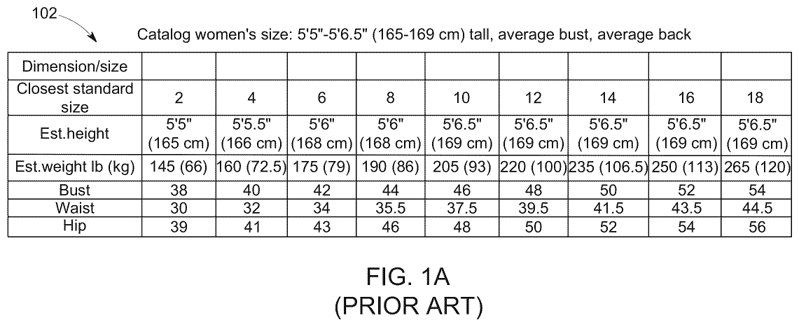

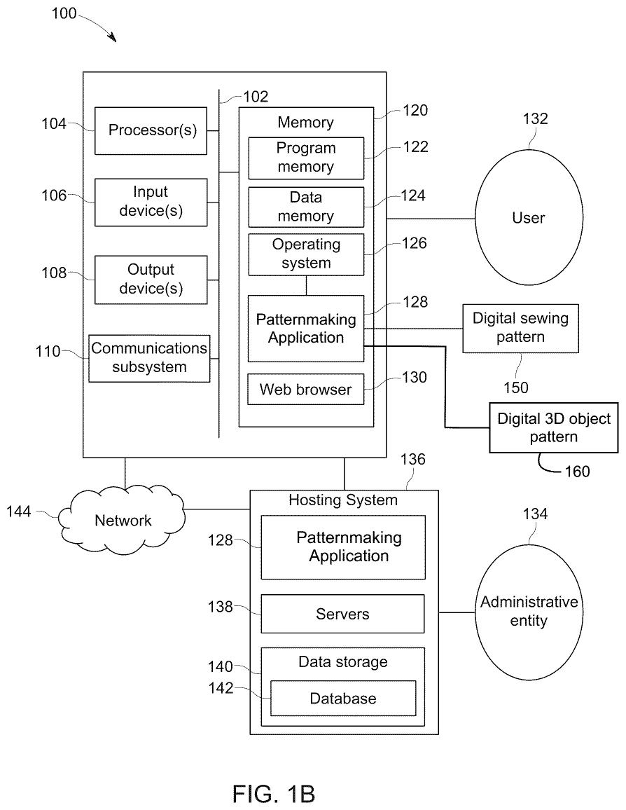

Some embodiments are described herein as processes and depicted as flow diagrams or block diagrams. Although operations may be described as sequential, many operations can be performed in parallel or concurrently. In addition, the order of the operations may be rearranged. A process may have additional steps not included in the figure. As described with reference to FIG. 1B, the methods may be implemented by hardware, software, firmware, middleware, microcode, hardware description languages, or any combination thereof. When implemented in software, firmware, middleware, or microcode, the program code or code segments to perform the associated tasks may be stored in a computer-readable storage medium. Processors may perform the associated tasks.

Patternmaking for apparel requires a great amount of skill and understanding as to how the clothing will appear when worn, the movement and draping of the garment, sewing, and designing. Patternmaking also requires an extensive understanding of mathematical formulas and concepts. Most patternmakers manually calculate changes to a pattern created for one size when adjusting the pattern to better fit a person of another size and shape. Conventional software applications are inadequate for adjusting to different body proportions and calculating all nuances required for complicated garments. This disclosure addresses these needs.

This disclosure describes a patternmaking software application that draws a pattern piece onto a drafting area based on certain provided measurements and calculated measurements. The user can edit a basic pattern, and the patternmaking application tracks those edits and how they relate to measurements/parameters set by the user. The user may save the pattern and reload the pattern to new parameters without losing any design changes. User-created designs can be used in conjunction with body scanner or object scanner technology that provides a thorough set of measurements (e.g., 100+ measurements in some embodiments) relating to a clothing article or a 3D object. A series of anchor points may be tied through various mathematical functions to relevant measurements. The user can add design details or points to this framework and choose how they should be linked to the framework. Frameworks of different pattern options may advantageously contain if/else clauses that cover differences in body or object proportions and enable the user to adapt and create patterns that can be used for clothing articles or 3D objects without requiring in-depth knowledge of the nuances of pattern fit issues.

The patternmaking application of this disclosure may be used for bespoke clothing articles, made-to-measure clothing articles, other types of clothing articles, and 3D objects. Bespoke clothing may be entirely made from scratch based on a customer's specifications with far more attention to minute details related to fit. Bespoke clothing articles typically rely on multiple fittings during the pattern and clothing creation process to ensure an accurate and perfect fit for the intended wearer. Made-to-measure clothing refers to custom clothing that is cut to suit the dimensions of a particular body shape and size and sewn using a standard-sized base pattern. Suits and sport coats are examples of very common made-to-measure clothing articles or garments. “Custom made” is another way to refer to made-to-measure clothing. The fit of a made-to-measure clothing article or garment is typically superior to that of a ready-to-wear clothing article or garment because made-to-measure clothing articles are constructed to fit each customer individually based on body measurements that are used to customize a pre-existing pattern. Made-to-measure clothing articles or garments always involve some form of standardization in the pattern and manufacturing. A made-to-measure clothing article will usually be more expensive than a ready-to-wear clothing article but less expensive than a bespoke clothing article because the bespoke clothing article is made from scratch and involves many design changes and edits.

FIG. 1B is a block diagram of an exemplary computing device 100 and additional components for implementing a patternmaking system and method in accordance with this disclosure. Computing device 100 may belong to a user 132, for example, that intends to access patternmaking application 128. FIG. 1B is only a generalized illustration of various components, any or all of which may be utilized as appropriate, and broadly illustrates how individual system elements may be implemented in a relatively separated or a relatively integrated manner.

Computing device 100 may be any type of fixed in place or mobile computing device that is known or created in the future. Examples of fixed in place computing devices include, without limitation, desktop computers, workstation computers, servers, mainframe computers, host computer systems, remote kiosks/terminals, point-of-sale devices, set-top boxes, and any type of information handling system. Examples of mobile computing devices include, without limitation, laptop computers, smart phones, mobile phones, tablets, notebooks, wearable devices such as watches and glasses, personal digital assistants (PDAs), personal entertainment devices, MP3 players, portable televisions, and compact disc (CD) players.

Computing device 100 comprises processor(s) 104, input device(s) 106, output device(s) 108, memory 120, and communications subsystem 110 that are electrically coupled via bus 102 or otherwise in communication, as appropriate. Processor(s) 104 may include, without limitation, general-purpose processors and special-purpose processors such as digital signal processors, graphics acceleration processors, and the like. Input devices 106 may include, without limitation, cameras, sensors (such as inertial sensors), a mouse, a keyboard and the like. Output device(s) 108 may include, without limitation, a display monitor or screen. Input device 106 and output device 108 may be integrated, for example, in a touch screen or capacitive display.

Memory 120 may include both read-only and writable memory and may include various hardware devices for volatile and non-volatile storage. For example, memory 120 may comprise random access memory (RAM), CPU registers, read-only memory (ROM), and writable non-volatile memory, such as flash memory, hard drives, floppy disks, CDs, DVDs, magnetic storage devices, tape drives, device buffers, and so on. Memory 120 is non-transitory and is not a propagating signal divorced from underlying hardware. Memory 120 may comprise program memory 122 for storing programs and software, such as operating system 126, patternmaking application 128, and other programs or applications. Memory 120 may also comprise data memory 124 for storing data such as database query results, configuration data, settings, user options or preferences, etc., which may be provided to program memory 122 or other components of computing device 100.

Computing device 100 may be in communication with or further include storage devices such as local and network accessible storage, disk drives, drive arrays, optical storage devices, solid-state storage devices such as a RAM or a ROM, which can be programmable, flash-updateable and the like. Such storage devices may be configured to implement appropriate data storage configurations such as file systems, database structures, and the like. The storage devices may be removable storage devices that can be shared among multiple computing devices such as by connecting the removable storage device to a USB port or other connector.

Communications subsystem 110 permits data to be exchanged with network 144 and other computer systems and devices. Communications subsystem 110 may include, without limitation, a modem, a wired or wireless network card, an infrared communication device, a wireless communication device or chipset (such as a Bluetooth™ device, an 802.11 device, a WiFi device, a WiMax device, cellular communication facilities, etc.), and the like.

Computing device 100 also comprises software elements or computer programs, shown as located within memory 120, which may include operating system 126, device drivers, executable libraries, and other code or instructions. Code or instructions may be read into memory 120 from a computer-readable storage medium incorporated within computing device 100, separate from computing device 100 (e.g., a removable medium such as a CD or USB stick), and/or may be provided in an installation package used to program, configure, and adapt a general-purpose computer with the code or instructions stored thereon. The instructions may take the form of executable code, which is executable by computing device 100, or may take the form of source or installable code, which upon compilation and/or installation on computing device 100 (using any suitable compiler, installation program, compression/decompression utility, etc.) then takes the form of executable code. Some or all of the procedures and methods described herein may be performed by computing device 100 in response to processor(s) 104 executing sequences of instructions incorporated into operating system 126 or contained in memory 120.

Substantial variations may be made in accordance with specific requirements. For example, customized hardware may be used and particular elements may be implemented in hardware, software (including portable software, such as applets, etc.), or both. Connection to other computing devices such as network input/output devices may be employed.

The terms “machine-readable” medium and “computer-readable” medium, as used herein, refer to any medium that participates in providing data that causes a machine to operate in a specific fashion. Various computer-readable media may be involved in providing instructions or code to processor(s) 104 for execution and in storing and carrying such instructions or code (e.g., as signals). A computer-readable medium may be a physical or tangible storage medium and may take many forms such as, for example, floppy disks, flexible disks, hard disks, magnetic tape, CD-ROMs, RAMs, PROMs, EPROMs, FLASH-EPROMs, other memory chips or cartridges, physical media with patterns of holes, carrier waves, and any other magnetic, optical or other media from which a computer can read instructions or code.

Computer-readable media include, without limitation, non-volatile, volatile, and transmission media. Non-volatile media may include, for example, optical or magnetic disks. Volatile media may include, for example, dynamic memory that may be included in memory 120. Transmission media may include, for example, coaxial cables, copper wire, fiber optics, wires that comprise bus 102, components of communications subsystem 110, and the media by which communications subsystem 110 communicates with other devices. Transmission media may also take the form of waves, such as acoustic waves, light waves, and those generated during radio-wave and infrared communications.

Various forms of computer-readable media may be involved in carrying sequences of instructions to processor(s) 104 for execution. In one non-limiting example, the instructions may be initially carried on a magnetic or optical disc of a remote computer. The remote computer may load the instructions into its dynamic memory and send the instructions as signals over a transmission medium to be received and executed by computing device 100. These signals, which may be in the form of electromagnetic, acoustic, optical signals and the like, are examples of carrier waves on which instructions can be encoded.

Communications subsystem 110 receives signals from computer-readable media as described above, and bus 102 then carries the signals (and the instructions carried by the signals) to memory 120. Processor(s) 104 then retrieves the instructions from memory 120 and executes the instructions. The instructions received by memory 120 may optionally be stored on a non-transitory storage device either before or after execution by processor(s) 104.

Computing device 100 is in communication with network(s) 144, which may include a system of terminals, gateways, and routers. Network 144 may be any type of network known in the art including, without limitation, a local area network (LAN) such as a company Intranet, a wireless local area network (WLAN), a metropolitan area network (MAN), a wide area network (WAN) such as the Internet, a public switched telephone network (PSTN) or other telecommunications network, or any other wireless network (including Wi-Fi), wireline network, or other network topology suitable for interconnecting computing devices and other information handling systems. Network 144 may be a private network, a public network, or a combination thereof.

Network 144 may employ one or more cellular access protocols or technologies for communication among mobile computing devices such as 2G, 3G, 4G, 5G, LTE (long term evolution), GSM (global system for mobile communication), GPRS (general packet radio services), GSM (enhanced data GSM environment), UMTS (universal mobile telecommunications service), AMPS (advanced mobile phone system), TDMA (time division multiple access), CDMA (code division multiple access), and other access technologies that may provide for broader coverage between computing devices that are in remote locations not accessible by other networks. Different types of data may be transmitted via network 144 via different protocols. Computing device 100 may act as a standalone device or as a peer machine in a peer-to-peer (distributed) network environment.

Web browser 130, which may be stored in memory 120 of computing device 100, may be any suitable web browser for accessing web applications such as patternmaking application 128 on computing device 100. Web applications are applications that are accessible by network 144 and may be located on the Internet. Web browser 130 may include hardware, software, and/or firmware operative to present a web application on display device 108 of computing device 100. Non-limiting examples of suitable web browsers include GOOGLE CHROME, MICROSOFT EDGE, APPLE SAFARI, and MOZILLA FIREFOX. Web browser 130 may be installed by the manufacturer or downloaded onto computing device 100.

In some embodiments, patternmaking application 128 may be a software program or module configured to create and edit digital sewing patterns 150 for clothing articles and digital 3D object patterns 160 for 3D objects. Digital patterns 150 and 160 may be sent to a digital cutting board, printed on paper for use in making and producing clothing articles and 3D objects, and exported as PDF, DXF, or other suitable file formats.

In some embodiments, patternmaking application 128 may be implemented as a web service, which is a software program or application that implements a set of tasks and is accessible from computing device(s) 100 over network(s) 144. In one implementation, patternmaking application 128 is implemented as a web service accessible via the Internet by web browser 130. When implemented as a web service, a user may invoke a series of web service calls via requests to server(s) 138 of hosting system 136 that hosts patternmaking application 128. In some embodiments, hosting system 136 may be a cloud-based type hosting system that makes applications, services, and resources (e.g., patternmaking application 128) available to users on demand via network 144 from server(s) 138 of the cloud computing provider. In FIG. 1B, for example, administrative entity 134 may be a cloud computing provider and may provide access to patternmaking application 128 from server(s) 138.

In some embodiments, hosting system 136 may be implemented as a web service with a corresponding set of web service application programming interfaces (APIs). The web service APIs may be implemented, for example, as a representational state transfer (REST)-based hypertext transfer protocol (HTTP) interface or a simple object access protocol (SOAP)-based interface. Any suitable programming language may be used to create or operate patternmaking application 128 as a web service, including, but not limited to .NET, JAVA, and XML. Patternmaking application 128 as a web service may use standardized industry protocol for the communication and may include well-defined protocols, such as service transport, XML messaging, service description, and service discovery layers in the web services protocol stack.

Hosting system 136 may include data storage 140 that provides access to data stored in database 142 to applications on computing device 100 that may be geographically remote. Data storage 140 of hosting system 136 may offer offsite data storage, offsite data backup and restore functionality, and storage functionality not implemented on computing device 100. For instance, hosting system 136 may be implemented such that applications executing on computing device 100 can store, retrieve, or otherwise manipulate data objects in data storage 140. Servers 138 may be implemented using any type of computing device. Hosting system 136 may include one or more machine learning trained models stored on servers 138 to perform instructions of patternmaking application 128.

In some embodiments, administrative entity 134 is the provider and creator of patternmaking application 128. Administrative entity 134 may provide the application programming interface (patternmaking application 128) for use by user 132. Administrative entity 134 may manipulate and alter patternmaking application 128 as stored in hosting system 136 to affect its operation and maintenance. Data storage 140 stores data associated with patternmaking application 128 in database 142 including, for example, all data obtained from user 132. While administrative entity 134 is depicted as a single entity communicating over network 144 and through hosting system 136, administrative entity 134 may alternatively be distributed over network 144 in multiple physical locations.

In some embodiments, patternmaking application 128 may be a downloadable software module that is stored directly on computing device 100, rather than acting as a web service accessible through web browser 130. Accordingly, user 132 may download and store patternmaking application 128 on computing device 100 as a computer-based application and software module that runs using the working engines and modules on computing device 100. In some embodiments, patternmaking application 128 may be preinstalled on computing device 100 by the manufacturer or other entity. Patternmaking application 128 may be innate, built into, or otherwise integrated into existing platforms such as, without limitation, a website, third-party program, iOS™, Android™, Snapchat™, Getty Images™, Instagram™, Facebook™, or any other platform capable of transmitting, receiving, and presenting data.

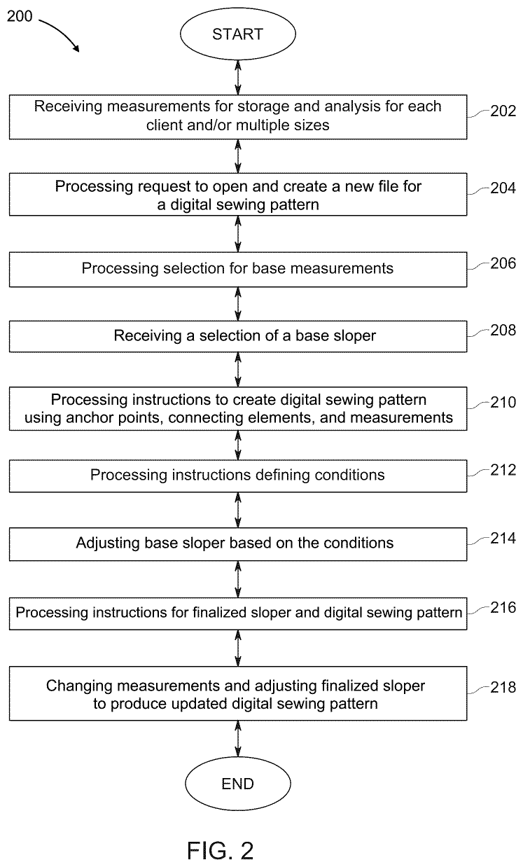

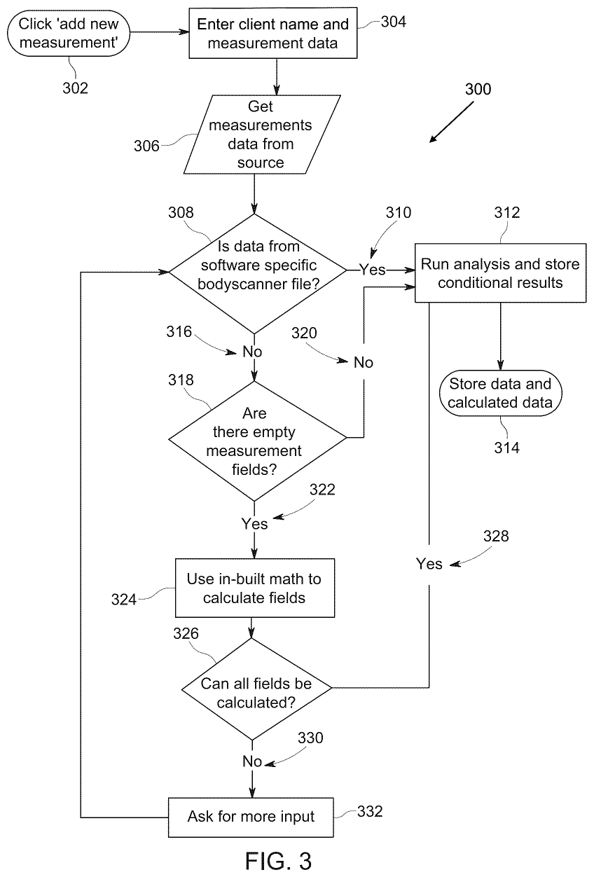

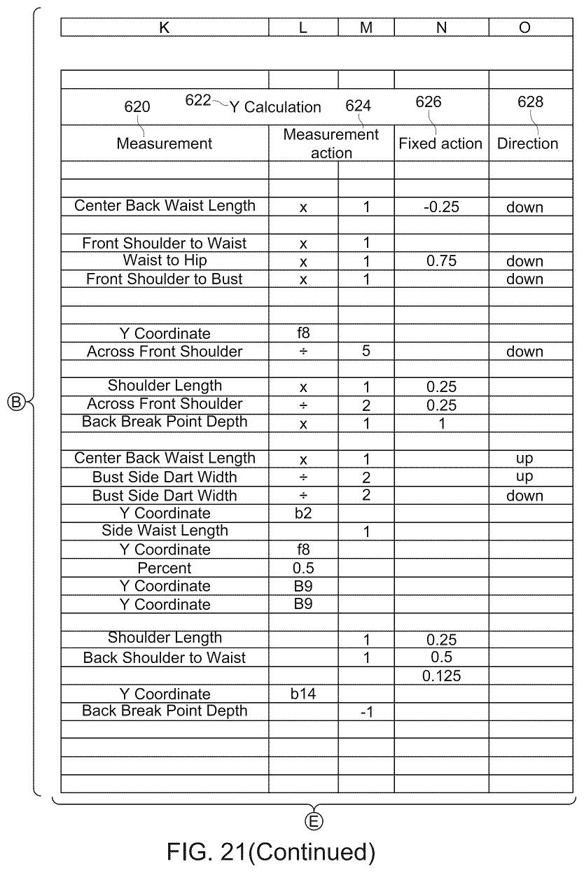

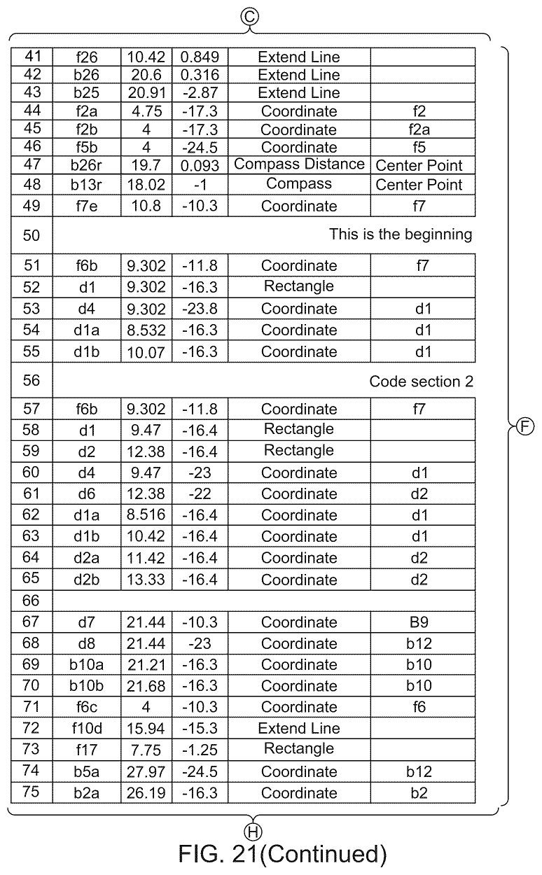

Patternmaking application 128 is now described in detail with reference to FIGS. 2-26. As mentioned above, patternmaking application 128 may be used to create digital sewing patterns usable to produce clothing articles, as well as digital 3D object patterns usable to create 3D objects. FIGS. 2-22 are described primarily in the context of creating digital sewing patterns, and FIGS. 23-26 relate primarily to the creation of digital 3D object patterns. It is important to note, however, that FIGS. 3-22 and their accompanying description are also substantially applicable to the creation of digital 3D object patterns. For sake of brevity and concise description, these figures and description are referenced but not repeated in full while describing the use of patternmaking application 128 to create digital 3D object patterns for 3D objects. Further, patternmaking application 128 may be configured to create both digital sewing patterns and digital 3D object patterns. That is, method 200 of FIG. 2 for creating a digital sewing pattern and method 2400 of FIG. 24 for creating a digital 3D object pattern may be combined and integrated into patternmaking application 128.

FIG. 2 is a flowchart of an exemplary method 200 of creating made-to-measure digital sewing patterns 150 using patternmaking application 128, in accordance with aspects of this disclosure. Importantly, the steps of method 200, and particularly steps 202-208, need not be carried out in any particular order. The term “draft-to-measure” may also be used to refer to digital sewing patterns 150 created by patternmaking application 128. Step 202 receives and stores measurements in patternmaking application 128 relating to a clothing article. In some embodiments, a body scanner provides measurements of a user's body. The body scanner may be a 3D type body scanner particularly suited for made-to-measure clothing. The body scanner scans a user's body from top to bottom in a matter of seconds and obtains numerous relevant and precise measurements for the whole body.

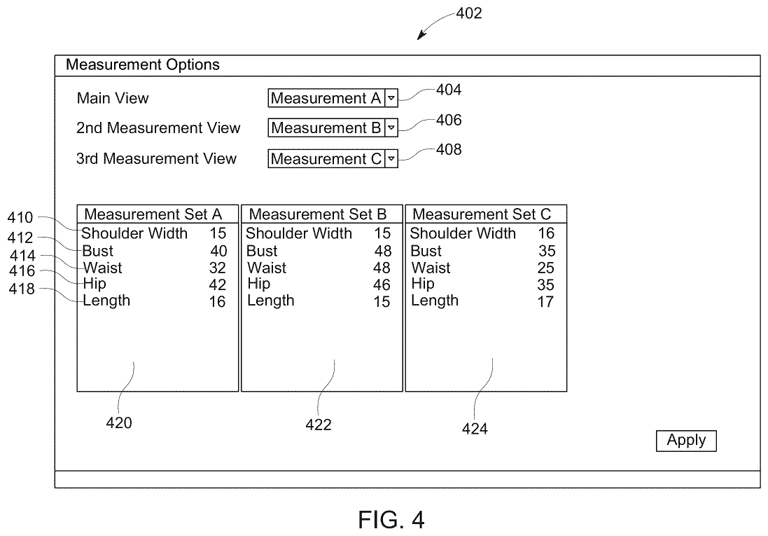

Measurements obtained from body scanners are usually considered more precise and accurate than measurements obtained manually or by hand, and can help to ensure that clothes made based on patterns using such measurements are more comfortable and have a better fit, so the user is more satisfied. That being said, step 202 may alternatively or additionally include manual measurements obtained by hand in which a tailor, seamstress, or other individual uses tools such as a tape measure to obtain and record relevant measurements such as shoulder width, bust, waist, hip, length, etc. (e.g., as shown in FIG. 4). Step 202 may combine hand and body scanner measurements. The measurements, however obtained and provided, may be stored in patternmaking application 128 and processed for analysis for each client and/or multiple sizes. One of the goals of patternmaking application 128 is to take a pattern created for one size, provide measurements for a larger or smaller size, and automatically edit the pattern to the larger or smaller size without requiring manual calculations by the user and incremental adjustments as is the case with traditional grading systems.

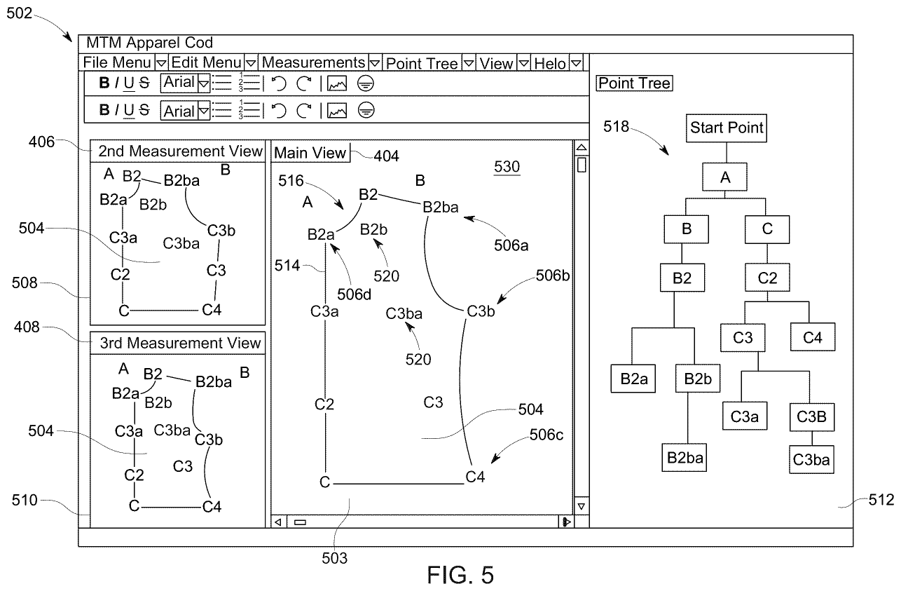

At step 204, patternmaking application 128 processes a request to open and create a new file for a specific digital sewing pattern. At step 206, patternmaking application 128 processes a selection for base measurements. Thus, user 132 selects base measurements needed for the pattern. At step 208, patternmaking application 128 receives and processes a selection for a base sloper. The term “sloper”, as understood in the art, refers to a basic pattern without any added design elements. An exemplary sloper 504 is shown, for example, in FIG. 5. A sloper is a 2D pattern version of a 3D form and represents the basic measurements of one's body and a clothing article or garment designed for one's body. Typically, commercial pattern producers use slopers that fit the “average” body shape, which is why ready to wear or store-bought clothes are not usually considered to be made-to-measure clothing. Patternmaking application 128 allows slopers created in patternmaking application 128 to accurately represent dimensions and measurements with precision and accuracy for a user's body and shape. A bodice sloper, for example, shows the length, width, and shape of one's torso, as well as the bust points and length of darts. Patternmaking application 128 may be used to create an apparel marker, which in apparel manufacturing is a special kind of stencil that illustrates how pattern pieces of garments should be cut from several layers of fabric. It is the marker planner's job to arrange the pattern pieces efficiently, wasting as little fabric as possible.

In some embodiments, patternmaking application 128 includes or accesses a database, such as database 142, storing a variety of base sloper templates relating to a variety of clothing articles from which user 132 may select. Advantageously, user 132 does not begin from a blank slate to create a digital sewing pattern. Rather, user 132 may select a base sloper from among the stored templates and modify it as needed, including with the use of conditional if/then statements, as described in detail below. The base sloper database includes a variety of base sloper templates for different kinds of clothing articles ranging from clothing worn on the body that can be categorized as casual, business related, dressy, formal, sportswear or activewear, pajamas or sleep attire, underwear and undergarments, socks, hats and headwear, and any other type of clothing article without limitation. Base slopers may be selectable by browsing or searching in the base sloper database of patternmaking application 128. Each base sloper may be categorized under a type of clothing or a type of digital pattern and in some cases may include a preview of the base sloper as well as a brief description that may be helpful in making a selection.

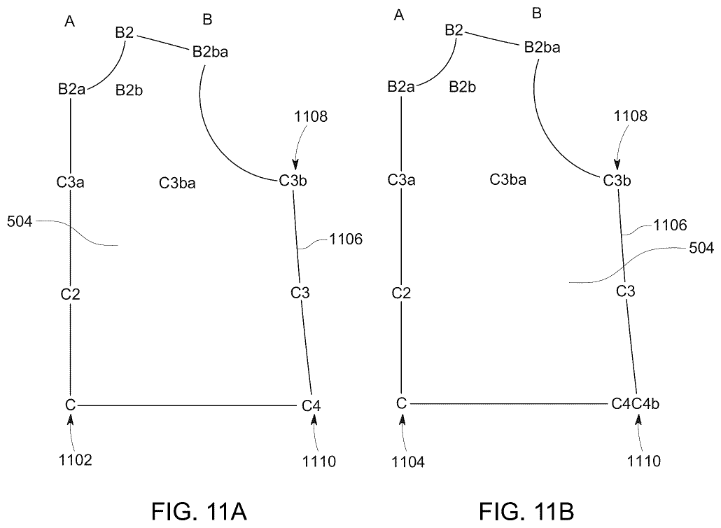

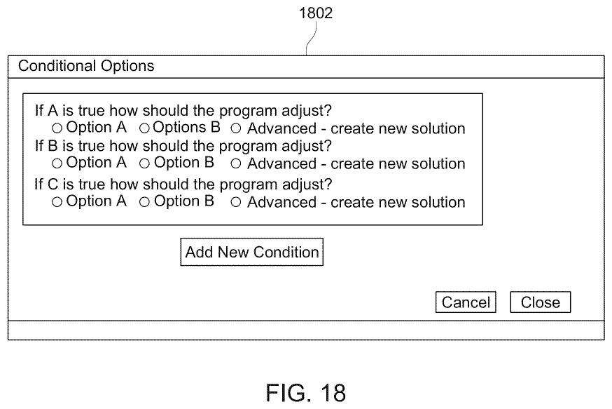

At step 210, patternmaking application 128 processes instructions to create a digital sewing pattern from the base sloper using anchor points, connecting elements, and measurements. At step 212, application 128 processes instructions defining conditions for handling or adjusting to certain measurements being greater than, less than, or some other variable as compared to the other (see FIGS. 12 and 19). In some embodiments, the conditions are if/then or if/else conditions. The base sloper is adjusted based on the conditions in step 214.

Step 216 processes instructions to finalize the base sloper into a finalized sloper, which corresponds to digital sewing pattern 150, for the entered set of base measurements and with the conditional results applied to the base sloper. At this point, digital sewing pattern 150 may be sent for processing to a manufacturer or designer, printed on paper and used to create clothing articles, exported as a PDF, DXF, or other file format, sent to a digital cutting table, and/or converted to a marker.

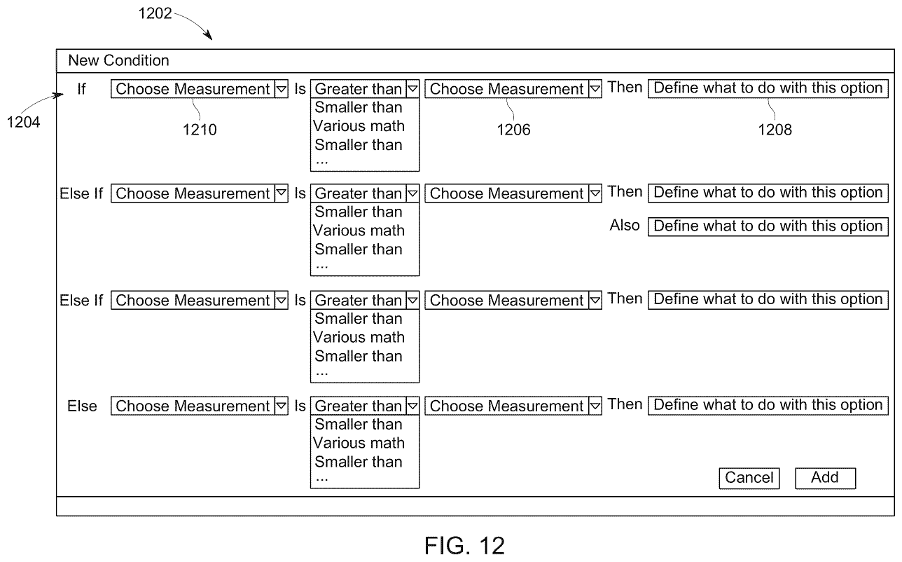

At step 218, the finalized sloper may be adjusted and changed to accommodate another size and set of base measurements. Accordingly, user 132 may enter new or changed measurements and any updated conditions, after which patternmaking application 128 automatically adjusts the finalized sloper to produce an updated digital sewing pattern for a different size or body type. Notably, user 132 does not need to start again from scratch to change the size or body/proportions that the finalized sloper relates or corresponds to. Rather, patternmaking application 128 includes an interface for user 132 to provide a new set of measurements and allows the sloper to be adjusted to the new measurements while taking into consideration any preferred design details and outcomes or added if/then clauses, which is further discussed below, especially with respect to FIGS. 13-21.

FIGS. 3-22 provide further details about steps 202-218 of method 200 for using patternmaking application 128 to create digital sewing patterns 150 for clothing articles. In this regard, it is important to note that the additional information about method 200 provided by FIGS. 3-22 is also applicable to method 2400 of FIG. 24 for creating digital 3D object patterns for 3D objects.

FIG. 3 is a flowchart of an exemplary method 300 for adding measurements to patternmaking application 128, in accordance with aspects of this disclosure. Step 202 of method 200 and step 2402 of FIG. 24, in which patternmaking application 128 receives measurements for storage and analysis, may incorporate some or all of the steps of method 300 of FIG. 3.

Addition of new measurements relating to a pattern for a clothing article is initiated in step 302 of method 300. At step 304, the name of the client or user and measurement data is entered. At step 306, the measurement data is obtained from a source, which may be a user that manually enters data measured by hand, or a body scanner from which patternmaking application 128 imports the measurement data. Unlike other applications, patternmaking application 128 is capable of storing, analyzing, and calculating relevant measurements or fields using hand measured data, imported body scanner measurements, or both. A body scanner can usually provide body measurements that cannot be obtained by hand. Thus, step 306 may allow user 132 to enter measurement sets that are less than complete in comparison with body scanner data.

Step 308 of method 300 queries whether the data is from a software specific body scanner file. If the data is from a software specific body scanner file (310—Yes), then patternmaking application 128 runs an analysis and stores conditional if/then results in step 312, and stores the data and the calculated data in step 314. In some embodiments, each client data set contains three elements: an original entry, a calculated measurement chart, and analysis results. The calculated measurement chart may calculate any missing fields that hand measuring techniques (non-scanner data) cannot measure. The list of answers provided by the analysis results may provide answers to body proportion questions, such as if the bust size is greater than the waist size for a client, then a specific outcome or result is applied to a pattern for that client.

If the data is not from a software specific body scanner file (316—No), then step 318 queries whether there are any empty measurement fields. If there are not any empty measurement fields (320—No), then patternmaking application 128 runs an analysis and stores conditional if/then results in step 312, and stores the data and the calculated data in step 314. If there are empty measurement fields (322—Yes), then patternmaking application 128 uses built-in mathematical formulas to calculate such empty fields in step 324 and determines whether all empty fields can be calculated in step 326. If all empty fields can be calculated (328—Yes), then step 312 runs an analysis and stores conditional if/else results and step 314 stores the data and the calculated data. If all empty fields cannot be calculated (330—No), then patternmaking application 128 requests further input in step 332.

FIG. 4 illustrates an exemplary base measurement interface 402 of patternmaking application 128 for receiving base measurements, in accordance with aspects of this disclosure. Base measurement interface 402 may be used in step 206 of method 200, for example, in which a selection for base measurements is processed. FIG. 4 is merely one example of how base measurement interface 402 may appear. Base measurements may be used for visual reference to build and make changes to a base sloper for a pattern or a set of related patterns. The base measurements may be changed at any time or default values may alternatively be used. The default values may include ASTM based measurements or more accurate measurements that do not rely only on proportional sizing measurements such as those used by ASTM.

In some embodiments, base measurements for three different body or object shapes are obtained so that user 132 can easily visualize how the pattern will appear in different situations. In particular, FIG. 4 shows that base measurement interface 402 allows for entry of three base measurement sets A, B, C, which are then visually displayed in main view 404, second measurement view 406, and third measurement view 408 of interface 502 of FIG. 5. Each measurement set A, B, C may include multiple body measurements such as shoulder width 410, bust 412, waist 414, hip 416, and length 418 that are respectively displayed in portions 420, 422, 424 of base measurement interface 402. For a digital 3D object pattern, appropriate object measurements would be obtained and displayed. Measurement sets A, B, C may include measurement data provided by user 132 or another source, measurement data calculated by patternmaking application 128, or default values as described above.

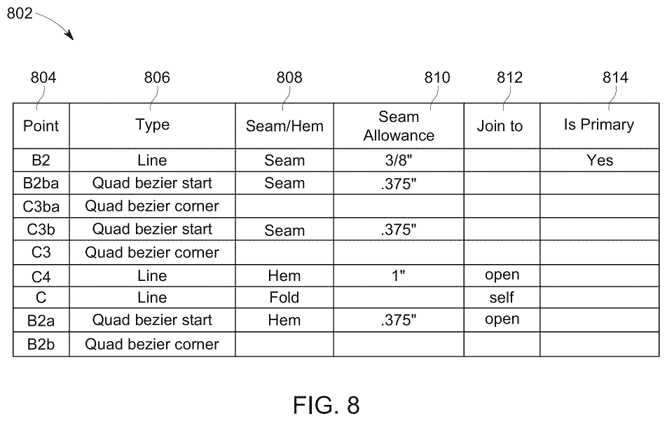

In some cases, user 132 may possess all data for measurement sets A, B, C. In other cases, in one or more measurement sets, user 132 only possesses data for the values of shoulder width 410, bust 412, waist 414, hip 416, and length 418. FIG. 4 usefully demonstrates that patternmaking application 128 can take measurement values for various sizes and proportions and generate a digital sewing pattern 150 (or digital 3D object pattern 160) for those various sizes that is accurate due to the ability to calculate critical values using built in mathematical equations and logic, and due to a conditional analysis in which a series of if/then conditional questions are asked (as shown in FIGS. 9, 12, 18). The conditions (results of the if/then questions) are stored and used to adjust base sloper 504, as shown in FIG. 5, to best suit the body and body proportions of a particular user or shape and proportions of a particular object.

The term “length” as used for measurement 418 may refer to various lengths. Base measurement interface 402 may provide cues for more specific types of length measurements in addition to shoulder width 410, bust 412, waist 414, and hip 416. For example, there may be additional entries for side waist length, which is the distance from the mid-underarm point of the arms eye to the waist level, taken along the side of the torso (contour), or for shoulder to elbow length, which is the distance from the top of the shoulder joint along the outside of the arm to the prominent point of the elbow, taken with the arm bent. These are merely some examples of the types of length measurements 418 that may be provided. Many other types of measurements may be added, such as the height of the user. The measurement fields shown in FIG. 4 are non-limiting, as the type of clothing article or 3D object for which user 132 is using patternmaking application 128 to generate a digital sewing pattern 150 or digital 3D object pattern 160 dictates the measurements that are required. Many other types of cues can be provided as well as definitions for the measurement fields requested in base measurement interface 402. In some embodiments, user 132 is first asked to indicate what type of clothing article or 3D object will be the subject of digital sewing pattern 150 or digital 3D object pattern 160, and then a list of relevant measurement fields is presented and defined by interface 402 so that user 132 can focus on obtaining those measurements that specifically relate to that type of clothing article or object.

FIG. 5 illustrates an exemplary interface 502 of patternmaking application 128 for visually displaying different examples of a sloper 504 for a specific type of clothing article (or a base 3D object template for a 3D object), in accordance with aspects of this disclosure. As noted, user 132 may first select a base sloper in step 208 of method 200 from a database having a variety of base sloper templates. Interface 502 shows base measurement sets A, B, C that were obtained via base measurement interface 402 (FIG. 4) as applied to base sloper 504. In particular, main view 404 shows measurement set A as applied to base sloper 504; second measurement view 406 shows measurement set B as applied to base sloper 504; and third measurement view 408 shows measurement set C as applied to base sloper 504. Main view 404 is shown in display area 503 of interface 502 (also referred to as editable canvas 530); second measurement view 406 is shown in display area 508 of interface 502; and third measurement view 408 is shown in display area 510 of interface 502. Accordingly, three different size views for base sloper 504 are shown in interface 502 of FIG. 5 for a specific type of clothing article or garment.

While FIG. 5 shows base sloper 504 adjusted to accommodate three different measurement sets A, B, C provided to patternmaking application 128, in some cases, patternmaking application 128 may only receive one set of measurements representing one intended wearer or object, in which case only one view of base sloper 504 (or base 3D object template) would be presented in interface 502. User 132 may subsequently provide other sets of measurements having different values and patternmaking application 128 may automatically modify and edit base sloper 504 based on the updated set of measurements reflecting a different size and body proportion. In some embodiments, patternmaking application 128 automatically modifies and edits base sloper 504 after evaluating which design changes to make to base sloper 504 to best suit the body type of the wearer as evaluated based on the provided set of measurements and the conditions as applied to those measurements.

Each base sloper 504 displayed in the views of interface 502 may be an assembly of anchor points and connecting elements such as connecting lines, curves, and other geometric elements or shapes. Base sloper 504 shown in main view 404, for example, comprises anchor points 506 (e.g., anchor points 506a-506d), connecting lines 514, and curves 516. Each anchor point 506 is labeled. For example, each anchor point 506 may be labeled in alphanumeric order and by type. However, patternmaking application 128 permits user 132 to customize the labels of anchor points 506 to suit their preferences. For example, the anchor point labels may be customized to be something other than alphanumeric labels.

Some anchor points 506 correspond to control points 520 that may be used to control curves 516 in base sloper 504 between one or more points. Anchor point C3ba, for example, is a control point 520 that can be used to control the parametrization of the curve formed between point B2ba and point C3b. Likewise, anchor point B2b is a control point 520 used to control the curve formed between anchor point B2 and anchor point B2a. In some embodiments, user 132 can select a control point 520 and drag it in various directions (forward, back, up, down) to see the effect on the curve and on base sloper 504 as a whole.

Ultimately, the total combination of anchor points 506, lines 514, and curves 516 forms base sloper 504, and ultimately a digital sewing pattern 150, that can be used to cut and sew fabric or other material to form a clothing article. Connecting lines 514 and curves 516 are examples of connecting elements that may be used to create the design of base sloper 504. In some embodiments, the digital sewing pattern may comprise multiple sub-patterns or sub-slopers to form the whole digital sewing pattern for an article of clothing. For example, if the clothing article is a jacket, there may be sixty (or some other number) sub-patterns or sub-slopers that make up the complete sloper and that will then make up the digital sewing pattern 150 that is based off of the sloper. This is due to the fact that the jacket is comprised of multiple components, such as the inner lining, outer jacket material, collar, sleeves, etc. Thus, multiple sub-patterns or sub-slopers may be edited and arranged together to make up the finalized sloper for a digital sewing pattern 150.

In some embodiments, framework or point tree 518 is displayed in area 512 of interface 502. Framework tree 518 shows the connection of each anchor point 506 to another to clarify how connecting lines 514, curves 516 and other types of connecting elements interconnect anchor points 506. Base slopers 504 and base 3D object templates are basic building blocks that can be edited to create a final design for digital sewing pattern 150 or digital 3D object pattern 160. Each base sloper file contains a framework of calculations that will build the basis for a clothing article or 3D object that can be made from digital sewing pattern 150 or digital 3D object pattern produced by patternmaking application 128. In some embodiments, framework tree 518 for each base sloper 504 is locked by default to prevent accidental editing by user 132. User 132 may opt to unlock this default setting. Each base sloper 504 may contain connecting elements such as lines 514, curves 516, or other geometric elements that connect between anchor points 506. The other geometric elements comprise a wide variety of geometric shapes and elements such as, for example, rectangles, crosses, circles, faces, contours, and many other shapes.

Framework tree 518 serves as a base upon which to plot anchor points 506 and draw base sloper 504. In some embodiments, user 132 can add, manipulate, and move anchor points 506, connecting lines 514, curves 516, and other connecting elements on editable canvas 530 displayed on display 108 of computing device 100, which is a significant improvement relative to conventional software applications that may be used to create patterns.

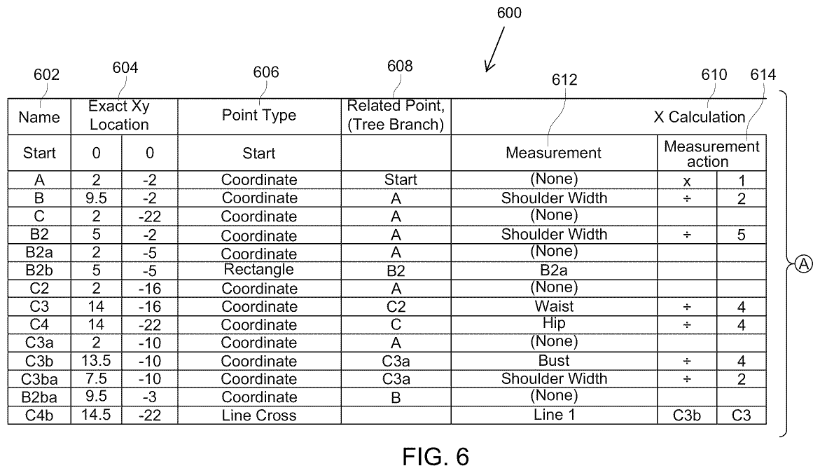

FIG. 6 is an exemplary table 600 listing components of base sloper 504, including anchor points 506, connecting lines 514, curves 516, and other geometric elements, in accordance with aspects of this disclosure. Table 600, which may be accessible to user 132 an displayed through patternmaking application 128, is a simplified example. Many sloper frameworks have 100 lines or more before any edits are added. Framework tree 518 makes it easier to follow each anchor point 506 back to its root point because of the way that framework tree 518 is laid out.

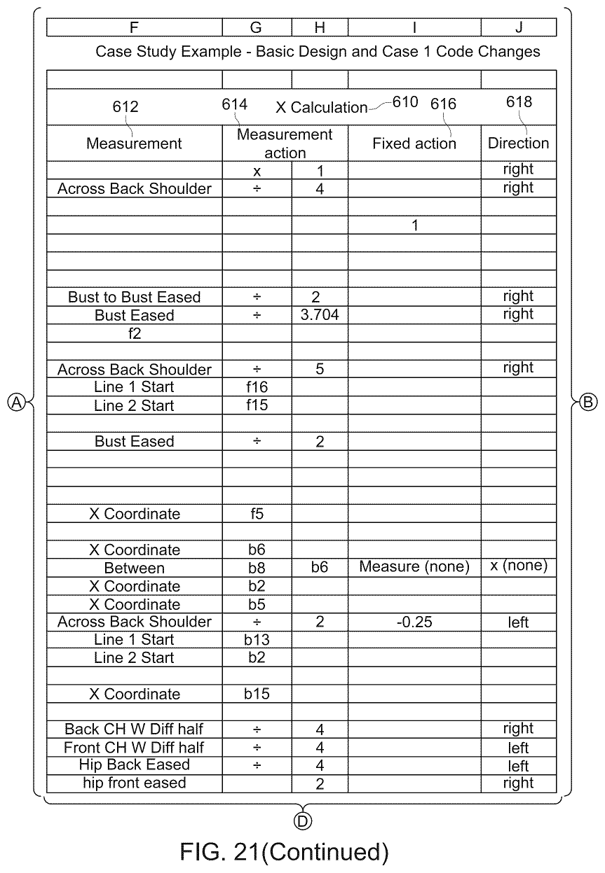

When producing a digital sewing pattern, patternmaking application 128 uses an X-Y grid to plot the locations of anchor points. FIG. 22 illustrates an exemplary X-Y grid 2202 used by patternmaking application 128 to plot locations of anchor points, in accordance with aspects of this disclosure. X-Y grid 2202 is an example of a Cartesian coordinate grid having X axis 2204, Y axis 2206, and center point 2208 (0,0). As shown in FIG. 6, patternmaking application 128 is configured to plot anchor points 506 in a positive or negative X direction along X axis 2204 from center point 2208 and to plot anchor points 506 in a positive or negative Y direction from center point 2208. User 132 may move or place anchor points 506 along X axis 2204 to design a pattern for a shoulder, hip, or waist of a garment, for example. Likewise, user 132 may move or place anchor points 506 along Y axis 2206 to design vertical connection lines and curves of the pattern, for example. In some embodiments, body measurements obtained by patternmaking application 128 may be related to the set of labeled anchor points 506 plotted along X-Y grid 2202 and the connecting elements connecting anchor points 506. In some embodiments, user 132 is able to create and add anchor points 506 to an existing base sloper 504.

Referring again to table 600 of FIG. 6, column 602 lists the name or label of each anchor point 506 of sloper 504. The names of anchor points 506 may be listed in alphanumeric order, for example. User 132 may provide other names or labels for anchor points 506 and cause them to be listed in a different order than alphanumeric. Column 604 lists the exact X-Y location of each anchor point 506 as plotted on an X-Y grid, such as X-Y grid 2202 of FIG. 22. In particular, the X and Y coordinates are indicated based on their negative or positive distance from center point 2208 on the X-Y grid. Anchor point A, for example, has an X-location on X axis 2204 of “2” and a Y-location on Y axis 2206 of “−2”.

Column 606 of table 600 lists the type of each anchor point. Types of anchor points 506 include, for example, coordinates, lines, rectangles, line cross, compass cross, compass distance, distance, and other types as indicated by appropriate mathematical and geometric descriptions. Column 608 lists a related point for each anchor point as shown in framework tree 518 of FIG. 5. In this manner, patternmaking application 128 determines how each anchor point 506 relates to others. For example, column 608 indicates that anchor point B2b relates to anchor point B2. As shown in FIG. 5, point B2b is a control point for the curve formed between points B2a and B2. Thus, table 600 lists anchor points 506 and how they relate to each other.

Column 610 of table 600 lists the calculations used to create the X location of each anchor point 506. Sub-column 612 of column 610 lists which measurement value or field relates to each anchor point 506. Anchor point B, for example, relates to a shoulder width measurement. The measurement values are obtained from sources including manual measurements, imported data, and/or body scanner measurements. Patternmaking application 128 can thereby track and note which measurements relate to each anchor point 506 of a base sloper 504. As noted above, base sloper 504 correlates each measurement to the plotted anchor points 506 on display canvas 530. Sub-column 614 of X calculation column 610 lists the measurement actions and calculation used to create the X location of each anchor point 506. Thus, sub-column 614 indicates that a measurement action is taken along the X axis for anchor points A, B, B2, C3, C4, C3b, and C3ba. Sub-column 616 indicates any fixed action taken in the X direction for each anchor point, and sub-column 618 indicates the direction moved along the X axis (right or left) for each anchor point.

Column 622 of table 600 indicates the calculations used to create the Y location of each anchor point 506. Sub-column 620 of column 622 lists which measurement value or field relates to each anchor point 506. Sub-column 624 lists the measurement actions and calculation used to create the Y location of each anchor point 506. Sub-column 626 indicates any fixed action taken in the Y direction for each anchor point, and sub-column 628 indicates the direction moved along the Y axis (up or down) for each anchor point.

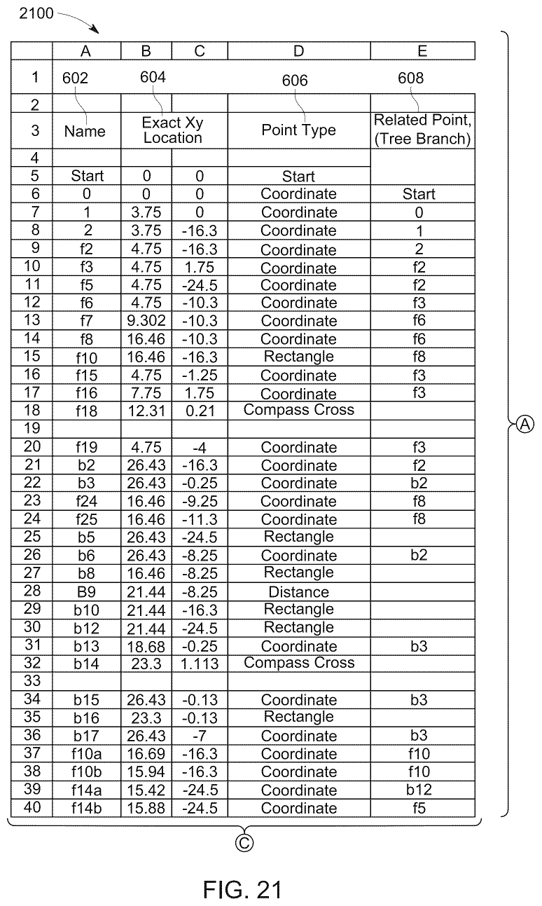

FIG. 21 is an exemplary table 2100 having the same organization as table 600 of FIG. 6 that lists components of a sloper or digital sewing pattern produced by patternmaking application 128 for the specific case example of FIGS. 13-17 of an exemplary suit jacket. Table 2100 will be described in more detail below, but for now, it is mentioned to illustrate that an actual sloper for a garment such as a suit jacket may have hundreds of anchor points. Thus, it is very helpful that patternmaking application 128 provides interfaces such as tables 600 and 2100 to show a listing of anchor points by name, how they are plotted and arranged on X-Y grid 2200, and how the measurement values obtained by patternmaking application 128 correlate to the anchor points.

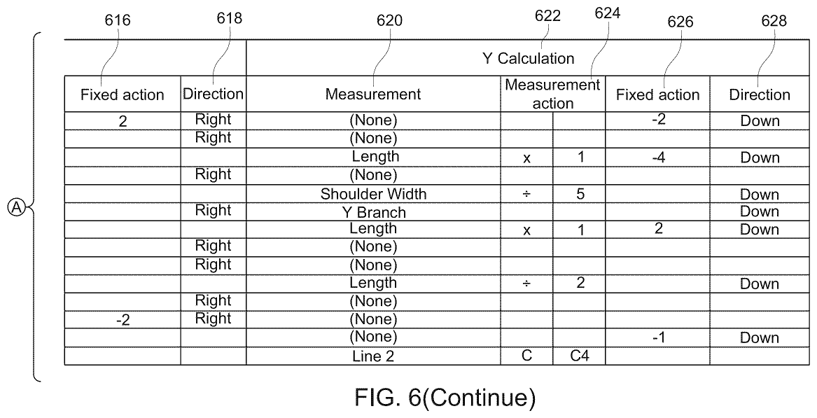

FIG. 7 is a flowchart of an exemplary method 700 for adding anchor points to a base sloper (or base 3D object template) and defining how the anchor points attach to the sloper, in accordance with aspects of this disclosure. Method 700 is an integral and important part of the process used by patternmaking application 128 to produce digital sewing patterns 150 and digital 3D object patterns 160. Step 210 of method 200 (and step 2410 of method 2400), in which patternmaking application 128 processes instructions to create a digital sewing pattern (or digital 3D object pattern) from the base sloper (or base 3D object template) using anchor points and connecting elements, may incorporate some or all of the steps of method 700 of FIG. 7.

An “Add point” tool is selected at step 702 to initiate method 700. At step 704, user 132 clicks on the line 514, curve 516, or other connecting element where the point is to be added. At step 706, a popup choice window with options A, B, and C is presented. Option A comprises step 708, in which a new point is added based on one other existing point, and step 710, in which the existing point is defined and its relation to the new point is added. Option B comprises step 712, in which a new point is added based on the distance between two existing points, and step 714, in which both existing points are defined and their relation to the new point is added. Option C comprises step 716, in which the new point is manually entered, and step 718, in which a calculation to determine the new point is entered. At step 720, the new point is named by the user and added to base sloper 504 or the base 3D object template.

In patternmaking application 128, pattern pieces or base sloper 504 may be drawn as paths between anchor points 506 whose location is defined by framework tree 518, as shown in FIG. 5, and the measurement calculations that place them. Clicking on anchor points 506 shows how and why anchor points 506 are placed where they are. The location of any point 506 in base sloper 504 can be changed by changing the how and why, thus keeping the pieces connected to the initial drawing rules and conditions. This connection between points 506 allows resizing of sloper or 3D object templates with relative ease in comparison with conventional options that require much more extensive patternmaking skills and knowledge. As noted above, conventional software applications typically do not allow a user to edit the base pattern piece or sloper once it is made. The user must often start from scratch to adjust measurements for another size, to accommodate a variation in design, or to move points already placed.

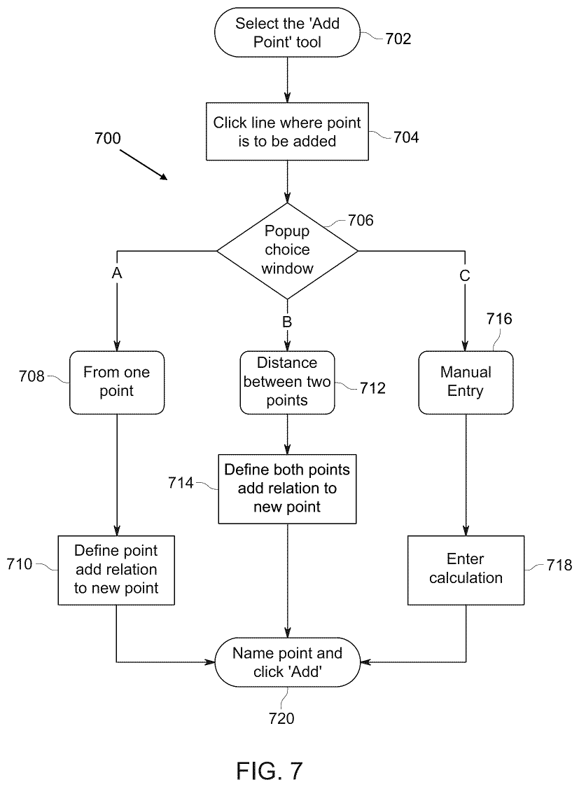

FIG. 8 is an exemplary table 802 listing values and data for lines, curves, or other geometric elements of a base sloper, in accordance with aspects of this disclosure. In the particular example of FIG. 8, table 802 indicates whether a line, curve, or other geometric element is associated with a seam, a hem or a fold. In this regard, a hem is an edge of a piece of clothing that has been turned under and sewn; a seam is a joint where two or more layers of fabric or other materials are held together with stitches; and a fold refers to a location where the sloper is folded. Multiple mathematical formulas and equations may be included or built into patternmaking application 128 to calculate the positioning of each anchor point 506, the positioning and connection of each connecting element, and how any curves or lines should appear on base sloper 504 for any seams, hems, or folds.

Table 802 may be displayed in an interface of patternmaking application 128. Column 804 of table 802 lists the name of the point, line, curve, or other geometric element. Column 806 indicates the type of line to draw, such as lines 514 and various types of Bezier curves. In this regard, application 128 includes and can perform a variety of complex mathematical formulas, equations, and calculation techniques, including but not limited to Bezier curves. Column 808 indicates whether the line, curve or other geometric object is a seam, a hem, or a fold.

Column 810 indicates the seam allowance (column 810), which refers to the area between the stitching and the raw, cut edge of the fabric and indicates how much extra fabric or other material may be needed around the edges for sewing purposes. The seam allowance is an important part of a seam and is usually inside the garment and unseen. In one embodiment, the seam allowance field is empty by default and may be filled optionally by user 132. Column 812 indicates which points, lines, or curves from another sub-sloper or sub-pattern that the line will be joined to. Column 814 indicates whether a line is primary. In this regard, application 128 may divide lines into categories of primary and non-primary. Primary lines cannot adjust in length, and non-primary lines self-adjust to match primary ones. The user can define which point to move to make the seams match. In most cases, adjustments are made in small amounts.

FIG. 9 is a flowchart of a method 900 for defining if/then conditions that may be used to determine a base sloper 504 or base 3D object template, according to aspects of this disclosure. In this description, “if/then” conditions may also be referred to as “if/else” conditions. Conditions, as described herein, relate to if/then clauses or statements that may be used to change how the base sloper or 3D object template framework is formed in certain situations depending on whether the if/then clause is determined to be true or false. These situations may be defined in the measurement analysis results and can be added to at any time. As further described below, FIG. 12 depicts an example conditions interface 1202 for specifying situations of interest to user 132.

Patternmaking application 128 opens the conditional options window or interface in step 902 of method 900. In some embodiments, conditional options are required for all files by default. However, this requirement can be disabled by user choice. At step 904, patternmaking application 128 presents multiple design choice options for known issues. User 132 may make selections for implementing the conditions, in some embodiments, from among a first option to apply default design details or changes, a second option to apply different design details or changes, and a third option to apply new conditions with new design details or changes. A window presenting the design choice options may also open automatically should calculation errors occur with a set of measurements. This is one reason for the measurement views of FIGS. 4 and 5, which allow user 132 to see how the pattern behaves with different sets of measurements.

At step 906, patternmaking application 128 queries whether all possible situations are covered. If all possible situations are covered (908—Yes), then user 132 may add additional situations where if/then clauses and conditions are needed (step 910). If all situations are not covered (912—No), then user 132 may opt to add a new condition (step 914) by defining the new condition (step 916) and adding the new condition to patternmaking application 128 (step 918). In some embodiments, in case of an error, an error window indicating which calculation failed is presented, and user 132 may enter a condition that corrects the issue. Large adjustments may automatically trigger a calculation error and open the conditional options window so that user 132 may select or create an option with a preferred design detail or change to correct the error.

In some cases, there may be predefined errors where certain measurements cause sloper 504 to move a point in a wrong way or an angle in a wrong direction making a pattern shape that has lines that cross over each other instead of making a desired shape. For example, a line cross that may calculate the point where two lines cross may find two lines that do not intersect at all. In this case, the conditional options window may pop up and ask user 132 for a design detail correction, suggested design detail corrections, or extra conditions.

In some embodiments, a machine learning trained module is configured to identify errors in the user selections for implementing the conditions. The machine learning trained module may apply new conditions with new design details or changes to the base sloper based on any errors identified by the machine learning trained module.

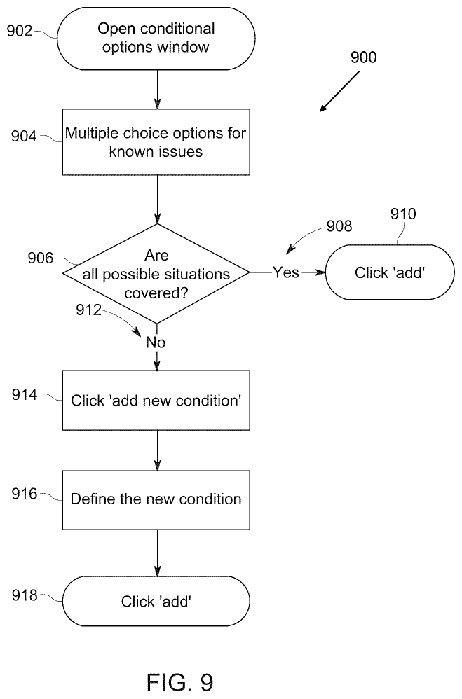

FIGS. 10A and 10B are “before” and “after” views of an exemplary base sloper 504 where a conditional change is made, in accordance with aspects of this disclosure. The views of FIGS. 10A-10B may be displayed in an interface of patternmaking application 128 so that user 132 can easily compare and contrast sloper 504 before and after the conditional change. In the example of FIGS. 10A-10B, sloper 504 incorporates second measurement set B of FIG. 4, where bust=48, waist=48, and hip=46. With respect to measurement set B, patternmaking application 128 determines that a waist<bust condition is false (48 is not less than 48) and that a waist<hip condition is also false (48 is not less than 46). In this case, user 132 has added a condition to patternmaking application 128 stating that if waist<hip, then change hip=waist. This condition causes the hip measurement to change from 46 to 48 because the waist measurement is 48.

FIGS. 10A and 10B show sloper 504 before and after this conditional change. In particular, FIG. 10A is a view of sloper 504 “before” the conditional change is made showing that there is a convex side seam extending from anchor point 1010 (C3b) to anchor point 1012 (C4). Thus, line 1004 connecting anchor point 1010 to anchor point 1012 is shown as a convex line. FIG. 10B is a view of sloper 504 “after” the conditional change is made showing that there is now a straight side seam line 1004 between points 1010 and 1012 after the analysis is performed by apparel patternmaking application 128 and the conditional change is made. Thus, the design detail or change that can be included as a default design detail when waist<bust is false and waist<hip is also false is to adjust the hip measurement to make a straight side in order to fit the body shape. In other instances, user 132 can enter this as a design detail, change, or outcome if it is not a listed pre-defined option or default.

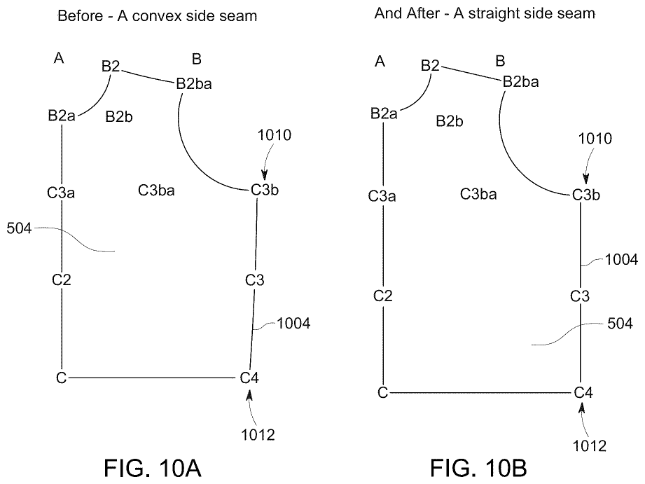

FIGS. 11A and 11B are “before” and “after” views of sloper 504 of FIG. 10 where a different conditional change is made, in accordance with aspects of this disclosure. The views of FIGS. 11A-11B may be displayed in an interface of patternmaking application 128 so that user 132 can easily compare and contrast sloper 504 before and after the conditional change. In the example of FIGS. 11A-11B, the bust measurement is 46 and the waist measurement is 48. Thus, waist<bust=false and waist>bust=true. The choice of user 132 and/or the default option provided in patternmaking application 128 may be to keep the bust and make the line 1106 or side seam extend outwardly by adding a new control point 1110 (e.g., new control point C4C4b as shown in interface 1104). FIG. 11A a view of sloper 504 “before” the conditional change is made showing seam 1106 connecting point 1108 and 1110, and FIG. 11B is a view of sloper 504 “after” the conditional change is made showing side seam 1106 adjusted after the analysis is performed by patternmaking application 128 and the conditional change is made.

FIG. 12 shows an exemplary conditions interface 1202 of patternmaking application 128 for selecting options for if/then conditional statements, in accordance with aspects of this disclosure. For example, conditions interface 1202 shows set up of a new condition 1204 in which the user defines a conditional result 1208 if a first chosen measurement 1210 is greater than, smaller than, equal to, or relates in another way (“various math”) to a second chosen measurement 1206. Conditions interface 1202 may allow user 132 to set up any number of such conditions 1204. As shown in FIG. 12, there are if/then clauses and if/else clauses that allow user 132 to specify or define a preferred outcome, when a measurement is either greater than, less than, equal to, or relates in another way to another measurement.

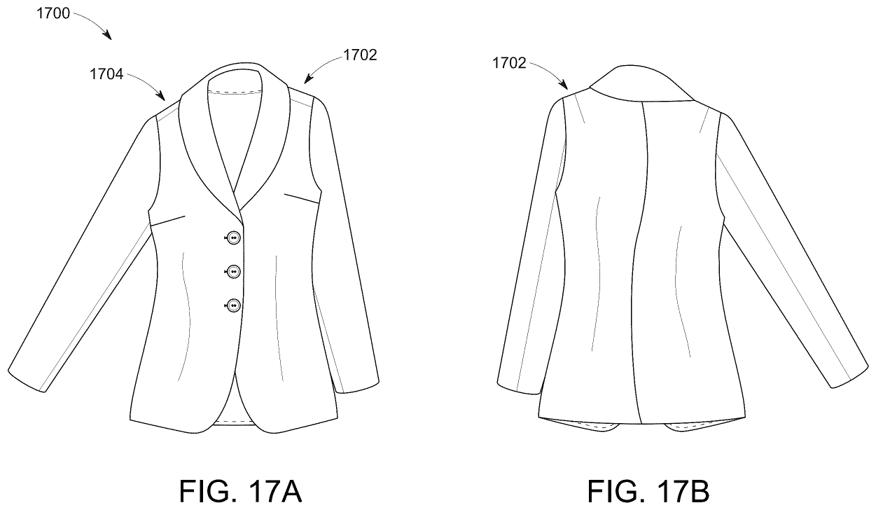

Accordingly, in some embodiments, patternmaking application 128 provides a conditions interface or window, such as those shown in FIGS. 12 and 18. These conditions interfaces use if/then statements and true/false fields, where a first chosen measurement 1210 is greater than, less than, equal to, or some other mathematical relation to, a second chosen measurement 1206. Patternmaking application 128 may provide user 132 with pre-defined options to select from in a field 1208, as shown in FIG. 12, or may allow user 132 to choose or define how a design change should be implemented on sloper 504. Accordingly, while user 132 may need some understanding about patternmaking and how clothes fit and are tailored, patternmaking application 128 assists user 132 in preparing a finalized sloper (or finalized 3D object template) that will become a digital sewing pattern 150 (or 3D object pattern 160) by prompting user 132 to consider certain proportion and size issues and the preferred design choice to handle such issues. The conditions interfaces and if/then statements are useful for addressing not just how measurements are plotted to anchor points 506 on a sloper 504, but also what design details or changes should be made to a sloper 504 to best fit an intended wearer who has certain body measurements. As noted above, patternmaking application 128 is intended to provide made to measure digital sewing patterns and digital 3D object patterns that provide clothing articles or objects that fit a desired form and shape as closely as possible.

There is no limit to the number of conditions that can be defined. Moreover, as shown in interface 1202 of FIG. 12, one condition may trigger more than one adjustment. Further, in some instances, one condition may trigger a section of framework tree 518 (FIG. 5) to be entirely replaced by a modification. This would then, in turn, modify anchor points 506 used for the related connecting element.

Once a finalized sloper (or finalized 3D object template) has been created for various sizes and approved by user 132, the clothing article or 3D object can be made based off of digital sewing pattern 150 or digital 3D object pattern 160 without having to begin from scratch. Clothing articles produced from digital sewing pattern 150 have a better fit for an intended wearer than generic articles of clothing because the finalized sloper used to create digital sewing pattern 150 includes the specific measurements of the wearer. Once the finalized sloper has been created having the correct style and matching the conditions for the if/then clauses, no editing phase should be needed for made-to-measure production runs. In comparison, conventional applications for creating sloper patterns require more time in the editing phase to properly edit a sloper. In particular, when an existing or previously created sloper must be adjusted for a particular shape or size in conventional applications, such adjustments must be performed manually and require extensive patternmaking skills.

Once digital sewing pattern 150 or digital 3D object pattern 160 is finalized, user 132 has multiple options for using the pattern to create an article of clothing. In some embodiments, patterns 150/160 may be printed on paper. In other embodiments, patterns 150/160 may be sent to a digital cutting system. In further embodiment, patterns 150/160 may be saved/exported as a PDF file, a DXF file, or as any other suitable type of image file.

As noted above, digital sewing pattern 150 may comprise a set of sub-patterns or sub-slopers that present or relate to certain portions/pieces of the digital sewing pattern 150. In some embodiments, the sub-patterns are assembled as a whole when printing or exporting digital sewing pattern 150. Alternatively, each sub-pattern that makes up digital sewing pattern 150 may be individually printed or exported. In some embodiments, the base sloper is the base template selected for a garment or clothing article, and the finalized sloper and digital sewing pattern 150 is the finalized, edited version of the base sloper. In some embodiments, as described above, the finalized sloper or digital sewing pattern 150 may be used to create a marker, which relates to the layout of the pattern pieces that a factory or production facility would use. Markers are made and arranged in such a manner to use as little fabric as possible.

FIGS. 13-18 illustrate different body proportion issues that can affect how an article of clothing appears and the design considerations that a designer or user of patternmaking application 128 must take into account. Before patternmaking application 128, there was no easy way to address the body proportion issues illustrated in FIGS. 13-18.

FIGS. 13A and 13B are front and rear views of an exemplary suit jacket 1300 made using a digital sewing pattern produced by apparel patternmaking application 128, in accordance with aspects of this disclosure. Three buttons 1304a, 1304b, and 1304c are integrated into suit jacket 1300 and aligned vertically (FIG. 13A). Suit jacket 1300 also includes first waist dart 1306 and second waist dart 1308 (FIG. 13A), and first shoulder dart 1310 and second should dart 1312 (FIG. 13B). Darts are used by dressmakers as a technique for shaping garments by curving straight fabric to the body. Darts are created by stitching a long, thin pinch to a point, which is then pressed down to one side. In other words, darts are two lines that are brought together to create the fold of fabric that is stitched. Darts usually have dart legs that are sewn from the widest point of the dart legs to the apex. Darts may be used and appear more often on the shoulders, waist, and bust of an article of clothing for shaping purposes.

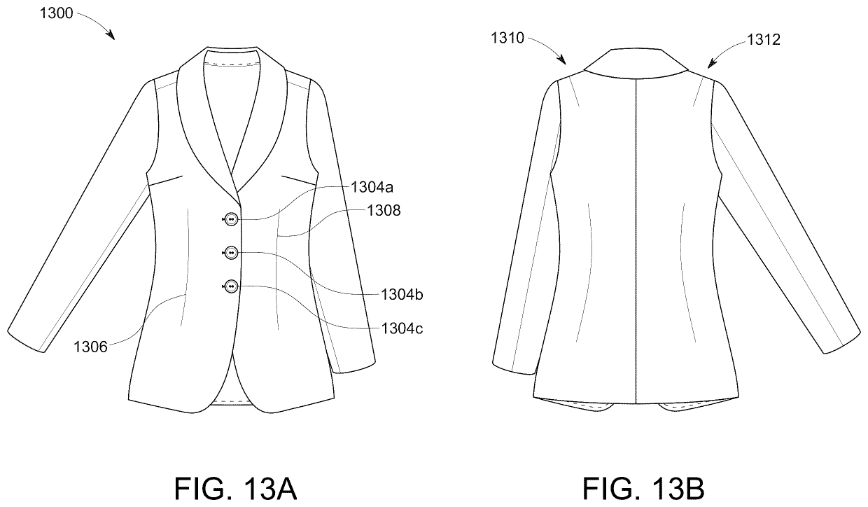

FIGS. 14A and 14B are front and rear views of a modified suit jacket 1400 made using the digital sewing pattern for suit jacket 1300 of FIGS. 13A-13B as modified by patternmaking application 128 to accommodate an intended wearer that has a narrow waist and a large hip, in accordance with aspects of this disclosure. In particular, the digital sewing pattern for suit jacket 1300 is modified in several ways by patternmaking application 128 to fit an intended wearer that has a narrow waist and a large hip. First, instead of two waist darts 1306 and 1308, four waist darts 1402, 1404, 1406, 1408 are included in the updated digital sewing pattern for suit jacket 1400 to better fit a wearer having narrower waist and larger hip measurements.

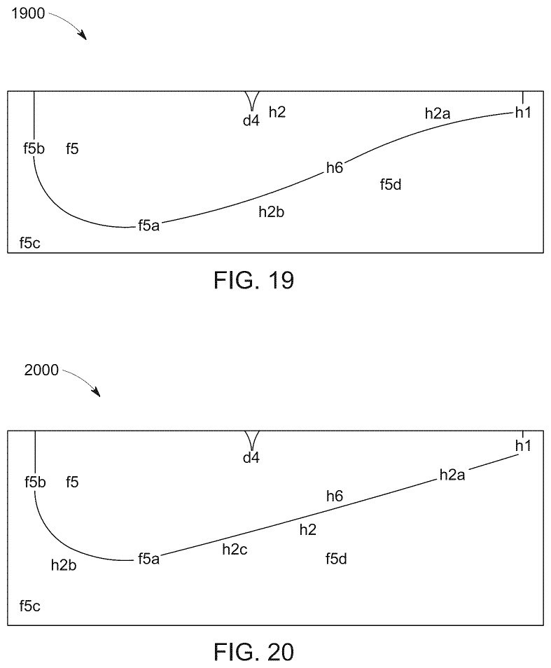

In addition, the inclusion of four waist darts 1402, 1404, 1406, and 1408 also triggers a code change for hem 1410 of suit jacket 1400. In particular, the narrower waist and larger hip measurements trigger a scenario that requires a double curve to be replaced with a single curve to maintain the seam allowance angles. This is illustrated in FIGS. 19 and 20, where FIG. 19 shows an exemplary double curve sloper 1900 for the hem of suit jacket 1300, and FIG. 20 shows an exemplary single curve sloper 2000 after a code change for hem 1410 of suit jacket 1400.

Table 2100 of FIG. 21 shows the myriad of code changes to the anchor points of the digital sewing pattern for suit jacket 1300 that are necessary to modify the digital sewing pattern to include four waist darts 1402-1408 (instead of two waist darts 1306 and 1308), and to modify the hem to incorporate a single curve 2000 (FIG. 20) rather than a double curve 1900 (FIG. 19). In particular, line 2104 of table 2100 documents the code change to the anchor points to correct the angles and to create a single curve for hem 1410.

FIG. 18 shows an exemplary conditions interface 1802 of patternmaking application 128, in accordance with aspects of this disclosure. Advantageously, patternmaking application 128 makes computations and calculations to adjust the positioning of anchor points 506 to accommodate different sets of proportion or size measurements that are based or partially based on the conditions that are set via interface 1802. Conditions interface 1802 may be presented by patternmaking application 128 in the same manner as conditions interface 1202 of FIG. 12. In some embodiments, interface 1802 may be used in conjunction with interface 1202, and in other embodiments, only one or the other of interfaces 1202 and 1802 may be used.

Conditions interface 1802 may present questions such as “If A is true how should the program adjust?”, “If B is true how should the program adjust?”, and “If C is true how should the program adjust?”, and allow the user to select option A or option B, or to create a new design solution or outcome. For the digital sewing pattern or sloper used to produce suit jacket 1300 of FIGS. 13A-13B, for example, if the front waist dart >1.5 inches, then the outcome may be that two waist darts are used rather than a single waist dart to provide the best shaping and fit. Accordingly, if front waist dart >1.5 inches, then one waist dart=False, and if front waist dart >1.5 inches, then two waist darts=True, would be the example condition entered into, defined by default, or otherwise selectable in patternmaking application 128. In this regard, table 2100 (FIG. 21) indicates at line 2102 how two waist darts 1402, 1404 are added to suit jacket 1400 instead of one waist dart 1306 in order to distribute the amount of fabric.

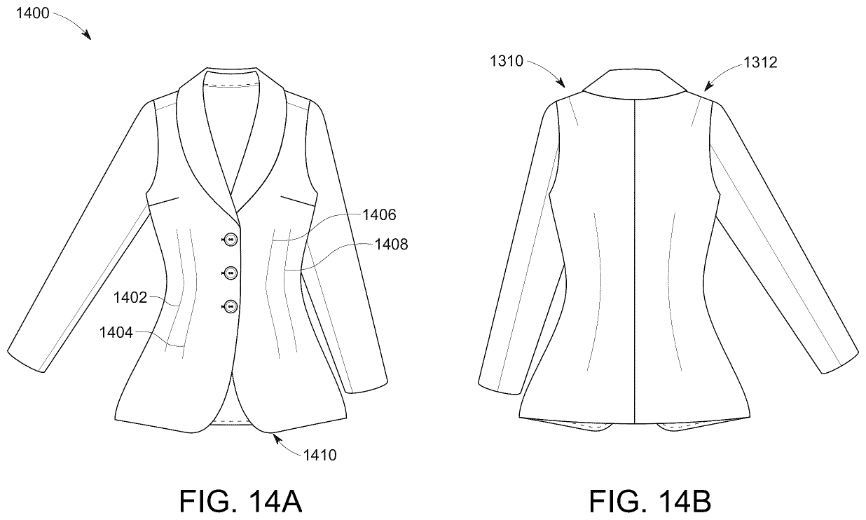

FIGS. 15A and 15B show another example of a suit jacket 1500 modified from its original form. In particular, FIGS. 15A and 15B are front and rear views of suit jacket 1500 made using the finalized sloper or digital sewing pattern for suit jacket 1300 of FIGS. 13A-13B as modified by patternmaking application 128 to accommodate an intended wearer that is smaller or of shorter height, in accordance with aspects of this disclosure. The digital sewing pattern or finalized sloper for suit jacket 1300 is modified in several ways by patternmaking application 128 to fit an intended wearer that is smaller or of shorter height. The codes associated with the finalized sloper or digital sewing pattern for suit jacket 1300 may be adjusted in many ways, including to provide only two buttons 1502, 1504 on the front of suit jacket 1500 rather than the three buttons 1304a, 1304b, and 1304c used for jacket 1300 intended for a taller person. The height difference may be taken into account with a design change that can be selected and tracked in conditions interface 1802 or conditions interface 1202.

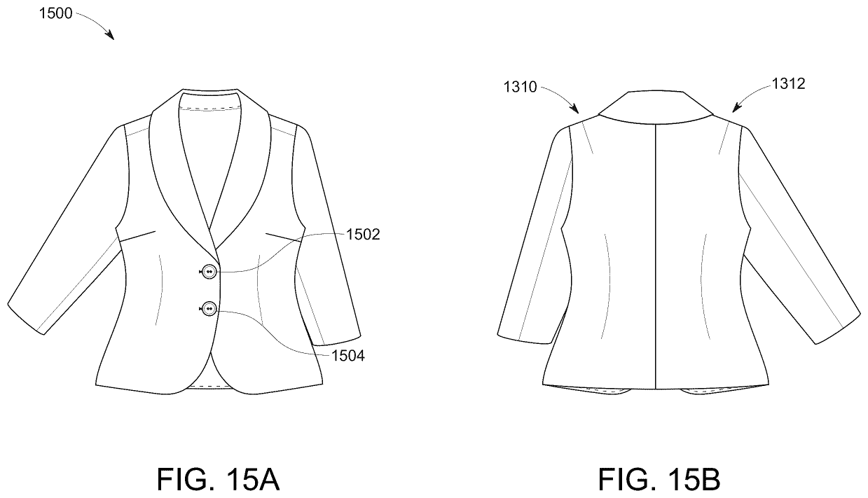

FIGS. 16A and 16B show another example of a suit jacket 1600 modified from its original form. In particular, FIGS. 16A and 16B are front and rear views of suit jacket 1600 made using the finalized sloper or digital sewing pattern for suit jacket 1300 of FIGS. 13A-13B as modified by patternmaking application 128 to accommodate an intended wearer that has wider shoulders, in accordance with aspects of this disclosure. The codes associated with the finalized sloper or digital sewing pattern for suit jacket 1300 may be modified to remove shoulder darts 1310 and 1312, as the wider shoulder for suit jacket 1600 does not require pinching darts. Patternmaking application 128 may thus take input provided by user 132 in conditions interfaces 1202 and/or 1802, or process instructions provided in default, pre-defined conditions, that state if the shoulder width measurements provided by user 132 or another source are wider than a certain value, then the shoulder darts should be removed from the sloper or digital sewing pattern and all anchor points 506, connecting elements, and the seams/hems/folds accordingly.

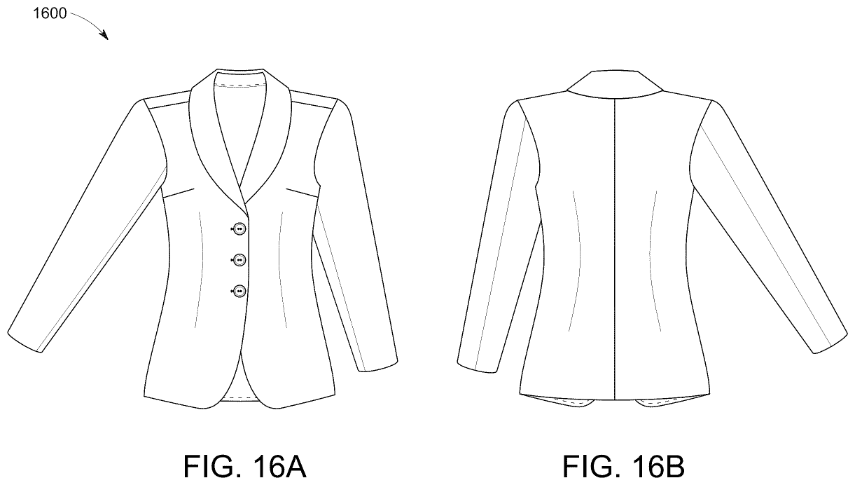

FIGS. 17A and 17B show another example of a suit jacket 1700 modified from its original form. In particular, FIGS. 17A and 17B are front and rear views of suit jacket 1700 made using the finalized sloper or digital sewing pattern for suit jacket 1300 of FIGS. 13A-13B as modified by patternmaking application 128 to accommodate an intended wearer that has one shoulder higher than the other shoulder, in accordance with aspects of this disclosure. This may occur, for example, where the intended wearer has scoliosis. The codes associated with the finalized sloper or digital sewing pattern for suit jacket 1300 may be modified to make right shoulder 1702 higher than left shoulder 1704 in suit jacket 1700.

As mentioned above, in addition to producing digital sewing patterns, patternmaking application 128 may implement a method for producing digital 3D object patterns. Some non-limiting examples of digital 3D object patterns that may be produced by patternmaking application 128 include, for example, digital 3D object patterns for custom shoe lasts, custom seat cushions, and custom avatars or physical body forms. Patternmaking application 128 as used for creating digital 3D object patterns is described primarily with reference to FIGS. 23-26. As mentioned above, the methods, tables, interfaces, etc. described with reference to FIGS. 3-22 for creation of digital sewing patterns are equally applicable to creation of digital 3D object patterns. Moreover, as also mentioned above, method 200 of FIG. 2 for creating a digital sewing pattern and method 2400 of FIG. 24 for creating a digital 3D object pattern may be combined and integrated into patternmaking application 128.

For 3D objects and patterns, patternmaking application 128 uses an X-Y-Z grid, such as X-Y-Z grid 2302 of FIG. 23, having X axis 2304, Y axis 2306, Z axis 2307, and center point 2308 (0,0). Patternmaking application 128 is configured to plot anchor points in a positive or negative X direction along X axis 2304 from center point 2308, in a positive or negative Y direction along Y axis 2306 from center point 2308, and in a positive or negative Z direction along Z axis 2307 from center point 2308. XY-plane 2310 is defined by X axis 2304 and Y axis 2306; XZ plane 2320 is defined by X axis 2304 and Z axis 2307; and YZ plane 2330 is defined by Y axis 2306 and Z axis 2307. Measurements obtained by patternmaking application 128 may be, for example, provided from a 3D body or object scanner or a 3D printer, and/or manually measured. Lines, curves, and other geometric elements may connect anchor points plotted along X-Y-Z grid 2302.

FIG. 24 is a flowchart of an exemplary method 2400 for creating a digital 3D object pattern 160 using patternmaking application 128, in accordance with aspects of this disclosure. Importantly, the steps of method 2400, and particularly steps 2402-2408, need not be carried out in any particular order. Step 2402 of method 2400 receives and stores measurements in patternmaking application 128 relating to a 3D object. The measurements may be provided, for example, by a 3D object scanner equipped to provide such measurements of an object. In some examples, the measurements may be provided by a 3D printer. Alternatively, or additionally, measurements may be obtained manually or by hand. Step 2402 may combine object or body scanner measurements and manual measurements. The measurements obtained in step 2402 are received by patternmaking application 128 for storage and analysis for each client and/or multiple sizes. As with digital sewing patterns, one of the goals of patternmaking application 128 is to take a 3D object pattern created for one size or shape of object, provide measurements for a different size or shape, and automatically edit the 3D object pattern to a different size or shape.

Step 2402, in which patternmaking application 128 receives measurements for storage and analysis, may incorporate some or all of the steps of method 300 of FIG. 3. For example, the measurement data may be obtained from a source, which may be a 3D object scanner or 3D printer from which patternmaking application 128 imports measurement data, and/or manual measurements made by hand. Patternmaking application 128 may determine whether there are empty measurement sets in the received measurements. If there are empty measurement fields, patternmaking application 128 may calculate values for the empty measurement fields using built-in mathematical equations included in patternmaking application 128. If the values for the empty measurement fields cannot be calculated, patternmaking application 128 may ask for more data to complete the empty measurement fields. Patternmaking application 128 may run an analysis and store conditional if/then results, the data input by user 132 or otherwise obtained, and the calculated data.

At step 2404, patternmaking application 128 processes a request to open and create a new file for a specific digital 3D object pattern. At step 2406, patternmaking application 128 processes a selection for base measurements. An interface such as base measurement interface 402 of FIG. 4, for example, may be used to obtain one or more sets of base measurements from user 132 or another source. In some instances, the base measurement data may comprise default values or may be calculated by patternmaking application 128 as described above. Thus, patternmaking application 128 can take measurement values for various 3D object sizes and proportions and generate a digital 3D object pattern 160 for those various sizes that is accurate due to the ability to calculate critical values using built in mathematical equations and logic, and due to a conditional analysis in which a series of if/then conditional questions are asked (as shown in FIGS. 9, 12, 18). The conditions (results of the if/then questions) are stored and used to adjust the base 3D object template to best suit the shape, size, and proportions of a particular object. In some embodiments, user 132 is first asked to indicate what type of 3D object will be the subject of digital 3D object pattern 160, and then a list of relevant measurement fields is presented and defined by interface 402 so that user 132 can focus on obtaining those measurements that specifically relate to that type of object.

At step 2408, patternmaking application 128 receives and processes a selection for a base 3D object template. The base 3D object template may be for a 3D object such as a shoe stay or a seat cushion that has a baseline size or shape. In some embodiments, patternmaking application 128 includes or accesses a database, such as database 142, storing a variety of base 3D object templates relating to a variety of 3D objects from which user 132 may select. Advantageously, user 132 does not begin from a blank slate to create a digital 3D object pattern. Rather, user 132 may select a base 3D object template from among the stored templates and modify it as needed, including with the use of conditional if/then statements, as described in detail below. Base 3D object templates may be selectable by browsing or searching in the base 3D object template database of patternmaking application 128. Each base 3D object template may be categorized by type of 3D object and in some cases may include a preview of the base 3D object template as well as a brief description that may be helpful in making a selection.

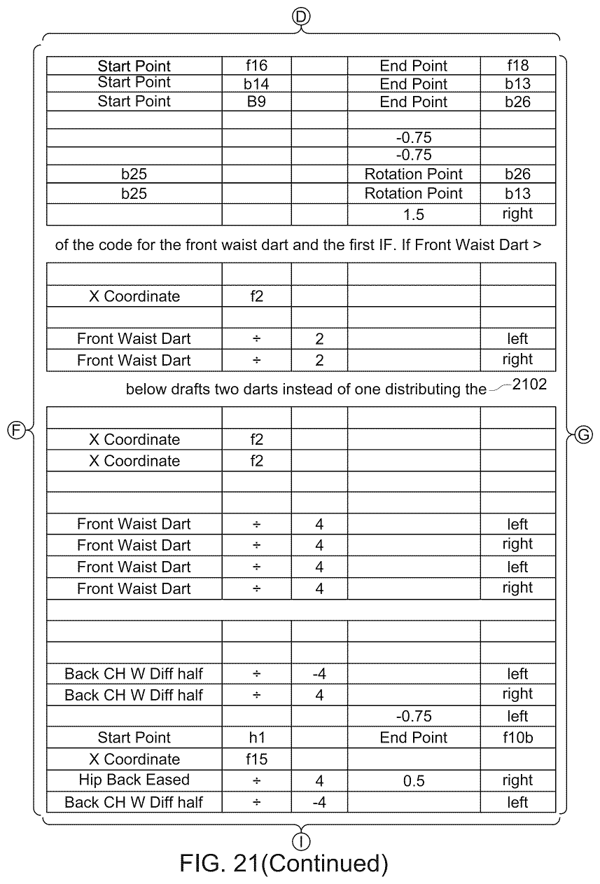

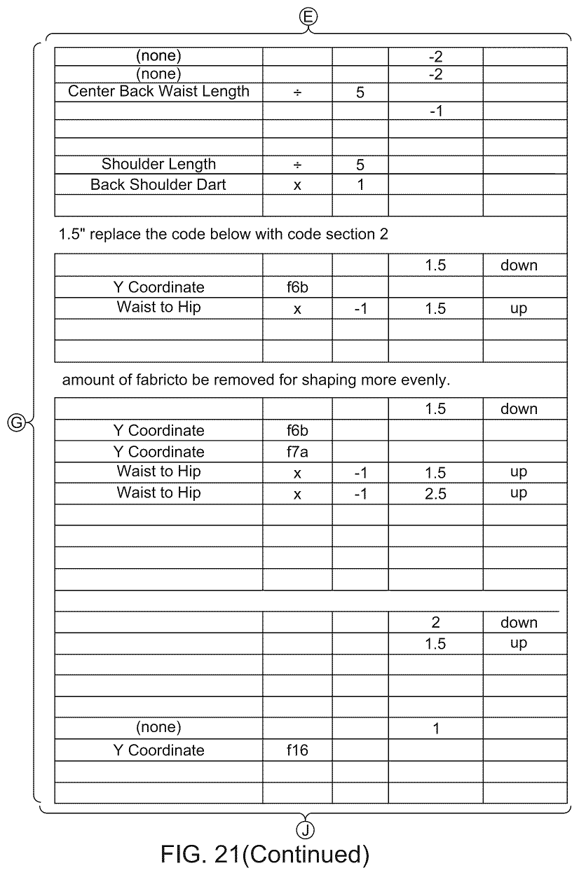

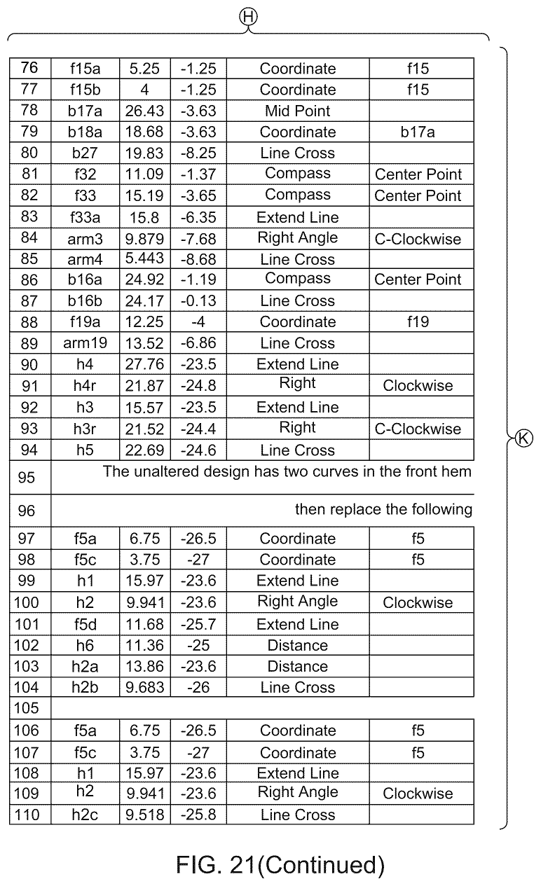

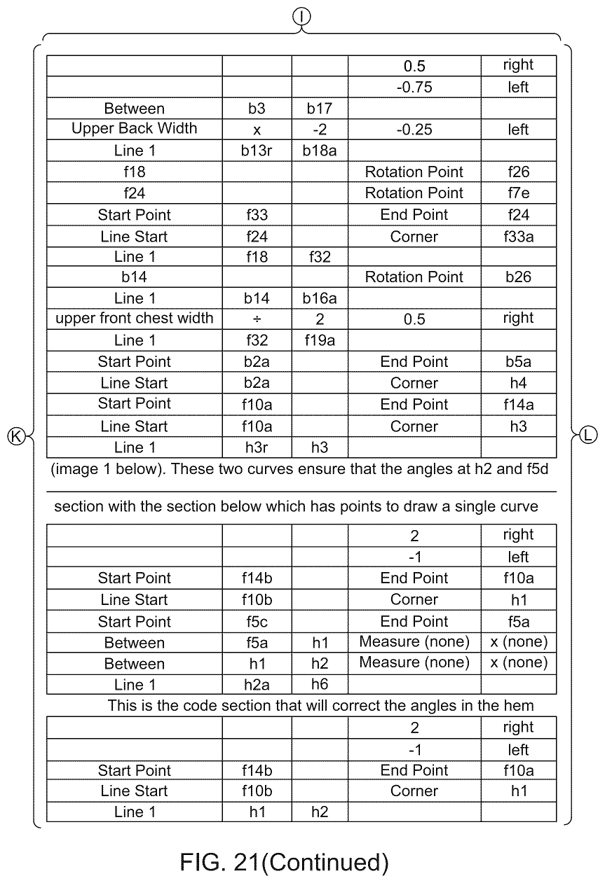

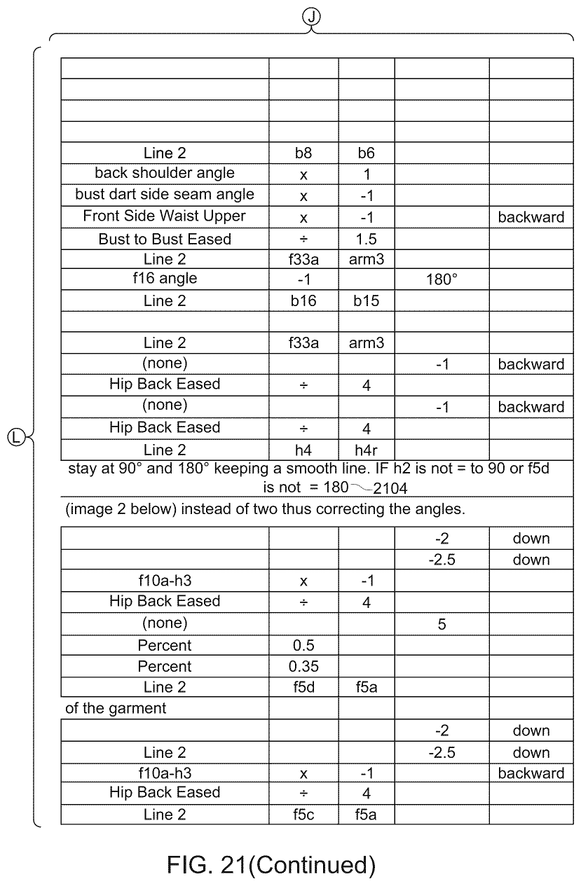

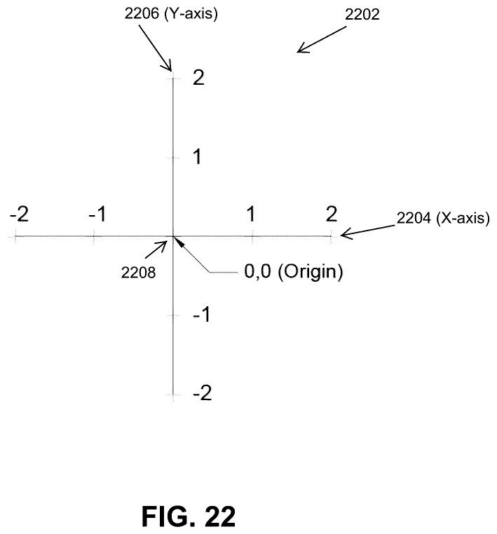

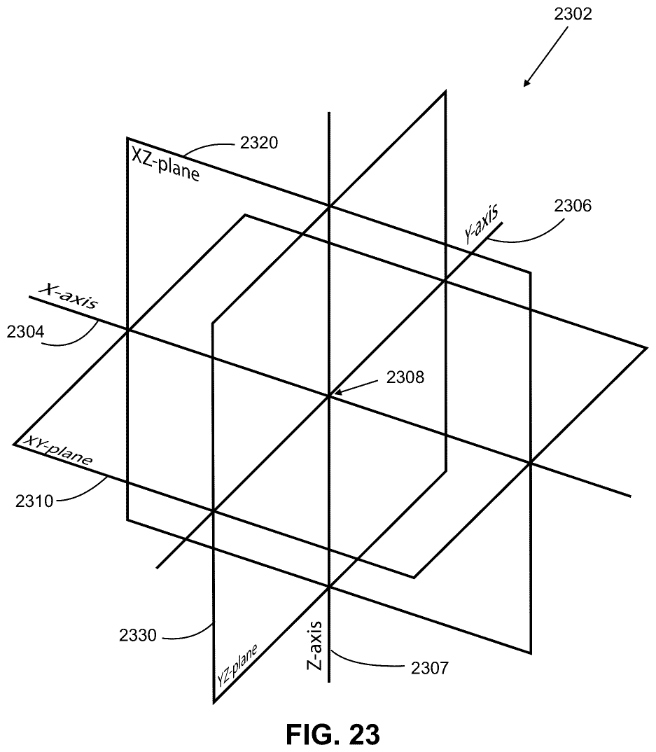

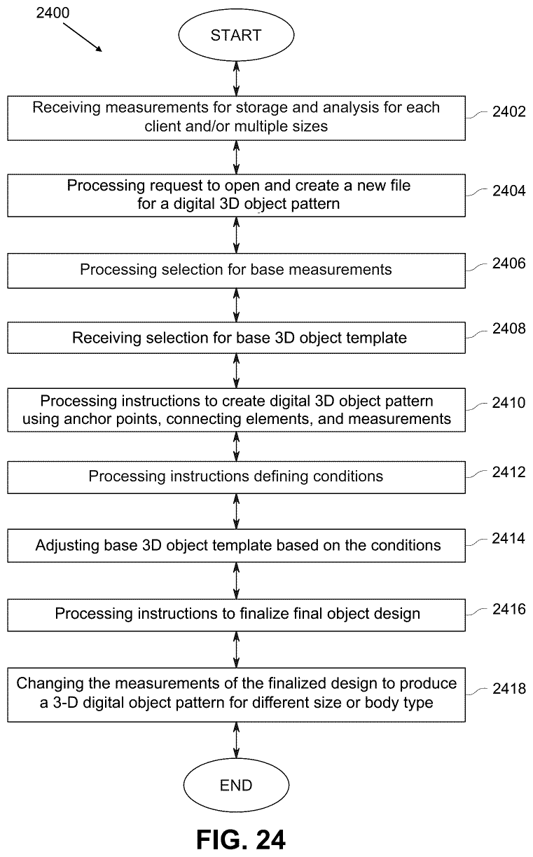

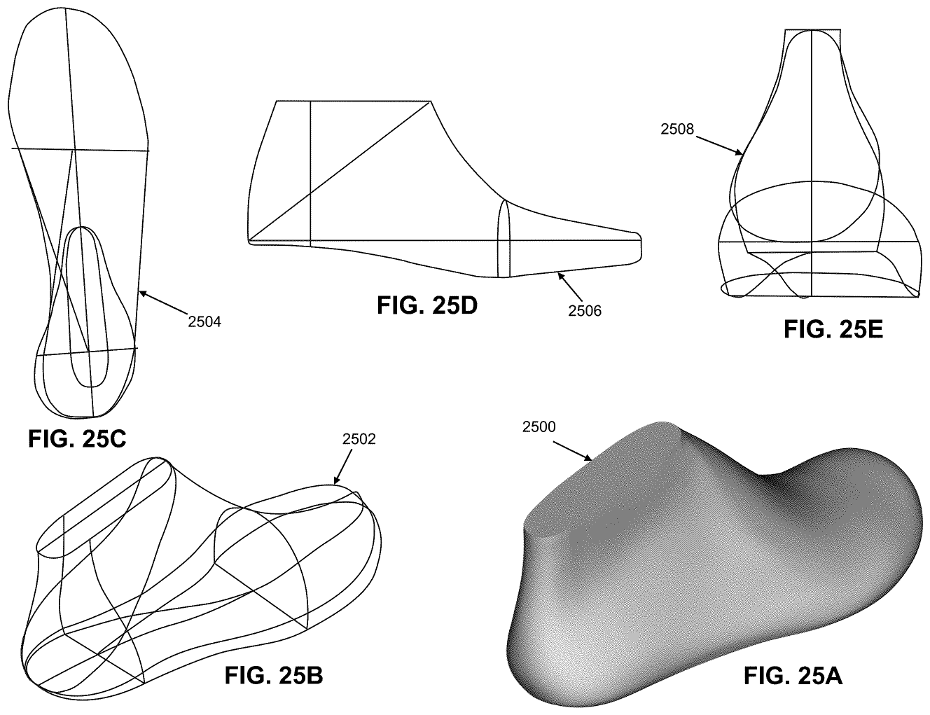

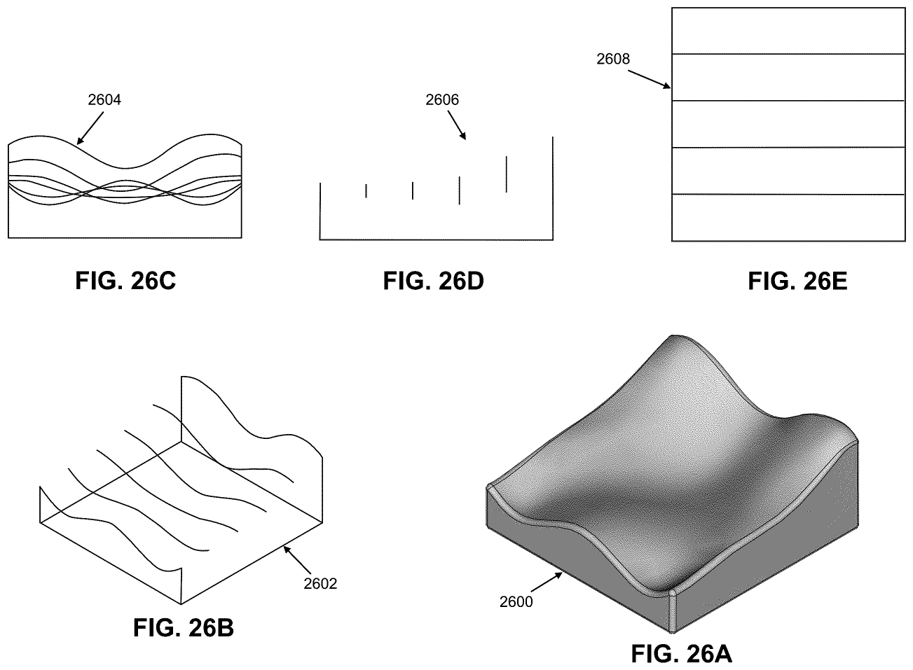

The database of initial objects may include a variety of base 3D object templates for virtually unlimited types of wearable and non-wearable 3D articles, items, and objects. An exemplary base 3D object template for a custom shoe stay 2500, for example, is illustrated in FIGS. 25A-25E. A base 3D object template, and ultimately digital 3D object pattern 160, typically comprises multiple sub-patterns or sub-templates that may be edited or arranged together to make up the 3D object template or digital 3D object pattern. The base 3D object template for shoe stay 2500 (FIG. 25A), for example, comprises 3D view sub-template 2502 (FIG. 25B), top view sub-template 2504 (FIG. 25C), side view sub-template 2506 (FIG. 25D), and back view sub-template 2508 (FIG. 25E). Another exemplary 3D object in the form of a custom seat cushion 2600 is shown in FIG. 26A. The base 3D object template for seat cushion 2600 comprises 3D view sub-template 2602 (FIG. 26B), front view sub-template 2604 (FIG. 26C), side view sub-template 2606 (FIG. 26D), and top view sub-template 2608 (FIG. 26E). It should be noted that the base 3D object templates illustrated in FIG. 26 are simplified for sake of explanation and may further comprise additional sub-templates. The complexity of the base 3D object template and the number of sub-templates required will depend on the type and complexity of the 3D object that is the subject of the base 3D object template.

At step 2410, patternmaking application 128 processes instructions to create a 3D object template or digital 3D object pattern using anchor points, connecting elements, and measurements. In this regard, patternmaking application 128 may visually display different examples of the base 3D object template for a specific type of clothing article 3D object in an interface such as interface 502 of patternmaking application 128. Multiple measurement sets may be applied to the base 3D object template to create the different examples, which may be displayed in multiple view areas of the interface, as described with reference to FIG. 5. In some instances, only one set of measurements may be provided and only one view of the base 3D object template incorporating those measurements may be displayed. User 132 may later provide updated measurements having different values and patternmaking application 128 may automatically modify and edit the 3D object template based on the updated measurements. In some embodiments, patternmaking application 128 automatically modifies and edits the base 3D object template after evaluating which design changes to make to the base 3D object template to best suit the shape, size, and proportions of the 3D object as evaluated based on the provided measurements and the conditions applied to those measurements.

The base 3D object templates may comprise an assembly of anchor points and connecting elements such as lines, curves, and other geometric elements or shapes, as shown in FIGS. 25-26, which may be displayed in an interface such as interface 502. Patternmaking application uses an X-Y-Z grid such as X-Y-Z grid 2302 of FIG. 23 to plot the locations of anchor points. The anchor points may be labeled by alphanumeric or other labels, and some anchor points may be control points for controlling the connecting elements.

A framework tree such as framework tree 518 may also show the interconnections between the anchor points and connecting elements and may be displayed in an interface such interface 502. As discussed above with respect to FIGS. 25-26, the base 3D object template may comprise multiple sub-templates or sub-patterns that are edited and arranged together to make up the finalized 3D object template. Each base 3D object template file contains a framework of calculations that will build the basis for a 3D object that can be made from digital 3D object pattern 160 produced by patternmaking application 128.

The anchor points and connecting elements comprising a 3D object template or a digital 3D object pattern may be listed in a table such as table 600 of FIG. 6, table 802 of FIG. 8, and/or table 2100 of FIG. 21. As in those tables, information such as anchor point names or labels, the X-Y-Z locations of the anchor points on X-Y-Z grid 2202, related anchor points, related measurements, and measurement actions and calculations used to create the X, Y, Z locations of the anchor points. The table may be displayed and accessible to user 132 through patternmaking application 128.

In some embodiments, user 132 can add, manipulate or move anchor points and connective elements on an editable canvas such as editable canvas 530 of FIG. 5 that is displayed on display 108 of computing device 100, which is a significant improvement relative to conventional software applications used to create patterns. Anchor points may be added to a base 3D object template using a method such as method 700 of FIG. 7, in which points are added based on an existing point, the distance between two existing points, and by manual entry. Clicking on the anchor points 506 may show how and why they are placed where they are. The location of any anchor point in the base 3D object template can be changed by changing the how and why, thus keeping the pieces connected per the initial rules and conditions. The connections between points allow resizing of 3D object templates with relative ease in comparison with conventional options and without starting from scratch.

At step 2412, patternmaking application 128 processes instructions defining conditions for handling or adjusting to certain measurements being greater than, less than, or some other variable as compared to the other. In some embodiments, the conditions are if/then or if/else conditions that are defined per a method such as method 900 of FIG. 9, including detection and correction of any errors associated with the conditions. A conditional options interface or window, such as interface 1202 of FIG. 12 and/or interface 1802 of FIG. 18, may be opened by patternmaking application 128 that presents multiple design choice options for known issues. The interface displays if/then statements and true/false fields, where a first chosen measurement 1210 is greater than, less than, equal to, or some other mathematical relation to, a second chosen measurement 1206. Patternmaking application 128 may provide user 132 with pre-defined options to select from in a field 1208, as shown in FIG. 12, or may allow user 132 to choose or define how a design change should be implemented.

In some embodiments, a machine learning trained module is configured to identify errors in the user selections for implementing the conditions. The machine learning trained module may apply new conditions with new design details or changes to the base 3D object template based on any errors identified by the machine learning trained module.

User 132 may make selections for implementing the conditions, in some embodiments, from among a first option to apply default design details or changes, a second option to apply different design details or changes, and a third option to apply new conditions with new design details or changes. Views of the base 3D object template before and after a condition is applied may be displayed in an interface of patternmaking application 128 so that user 132 can easily compare and contrast the 3D object template before and after the conditional change is analyzed and made by patternmaking application 128 (see, e.g., FIGS. 10-11). Referring again to FIG. 24, the base 3D object template is adjusted based on the selected conditions in step 2414.

Step 2416 processes instructions to finalize the base 3D object template into a finalized 3D object template, which corresponds to digital 3D object pattern 160, for the entered set of base measurements and with the conditions applied to the base 3D object template. At this point, digital 3D object pattern 160 may be sent for processing to a manufacturer or designer, printed on paper and used to create the 3D object, sent to a 3D printer to print the 3D object, and/or exported as a PDF, DXF, or other file format.

At step 2418, the finalized 3D object template may be adjusted and changed to accommodate another shape or size and set of base measurements. Accordingly, user 132 may enter new or changed measurements and any updated conditions, after which patternmaking application 128 automatically adjusts the finalized 3D object template to produce an updated digital 3D object pattern for a 3D object having a different size, shape, or proportions. User 132 does not need to start again from scratch to change the size, shape, or proportions of the 3D object that the finalized 3D object template relates or corresponds to. Rather, patternmaking application 128 includes an interface for user 132 to provide a new set of measurements and allows the 3D object template to be adjusted to the new measurements while taking into consideration any preferred design details and outcomes or added if/then clauses.

Accordingly, many advantages and benefits are provided by patternmaking application 128 as described above according to one or more non-limiting embodiments.

In this disclosure, claims, and drawings, reference is made to particular features and embodiments. This disclosure includes all possible combinations of such particular features and embodiments. For example, where a particular feature is disclosed in the context of a particular aspect or embodiment, or a particular claim, that feature can also be used, to the extent possible, in combination with or in the context of other particular aspects and embodiments.

The steps of the methods described in this disclosure can be carried out in any order or simultaneously, and the method may include one or more other steps that are carried out before any of the defined steps, between any of the defined steps, or after the defined steps, except where the context excludes these possibilities.

“Exemplary” is used herein to mean “serving as an example, instance, or illustration.” Any aspect described herein as “exemplary” is not necessarily preferred or advantageous over other aspects.

Throughout the drawings, like reference characters are used to designate like elements. As used herein, the term “coupled” or “coupling” may indicate a connection. The connection may be a direct or an indirect connection between one or more items. Further, the term “set” as used herein may denote one or more of any items, so a “set of items” may indicate the presence of only one item or may indicate more items. Thus, the term “set” may be equivalent to “one or more” as used herein.

The flowchart and block diagrams in the drawings illustrate the architecture, functionality, and operation of possible implementations of systems, methods, and computer program products according to various embodiments. In this regard, each block in the flowchart or block diagrams may represent a module, segment, or table of instructions, which comprises one or more executable instructions for implementing the specified logical function(s). In some alternative implementations, the functions noted in the block may occur out of the order noted in the figures. For example, blocks shown in succession may be executed substantially concurrently, or blocks may sometimes be executed in the reverse order, depending upon the functionality involved. Each block of the block diagrams and flowcharts, and combinations of blocks in the block diagrams and flowcharts, may be implemented by special purpose hardware-based systems that perform the specified functions or acts or carry out combinations of special purpose hardware and computer instructions, as described with reference to FIG. 1B.

The methods, systems, and devices discussed herein are examples. Various embodiments may omit, substitute, or add various procedures or components as appropriate. For instance, in alternative configurations, the methods described may be performed in an order different from that described, and various stages may be added, omitted, and/or combined. Also, features described with respect to certain embodiments may be combined in various other embodiments. Different aspects and elements of the embodiments may be combined in a similar manner. Technology evolves and many of the elements are examples that do not limit the scope of the disclosure to those specific examples.

The corresponding structures, materials, acts, and equivalents of all means or step plus function elements in the claims below are intended to include any structure, material, or act for performing the function in combination with other claimed elements as specifically claimed. This disclosure is presented for purposes of illustration and description but is not intended to be exhaustive or limited to the invention in the form disclosed. Many modifications and variations will be apparent to those of skill in the art without departing from the scope and spirit of this disclosure.

The embodiments were chosen and described in order to best explain the practical application and principles of the invention, and to enable those of skill in the art to understand the invention for various embodiments with various modifications as are suited to the particular use contemplated. The invention may be practiced with modification and alteration within the spirit and scope of the appended claims. Thus, this description is illustrative and not restrictive of the present invention.

What is claimed is:

1. A computer implemented method for producing a digital sewing pattern usable to produce a clothing article or a digital 3D object pattern usable to produce a 3D object, comprising:
receiving a request to open a file for the digital sewing pattern or for the digital 3D object pattern in a patternmaking application;
receiving and storing measurements in the patternmaking application relating to the clothing article or relating to the 3D object;
receiving a selection in the patternmaking application for a base sloper or for a base 3D object template;
displaying the base sloper or the base 3D object template in the patternmaking application, wherein the base sloper or the base 3D object template comprise anchor points connected by connecting elements including lines, curves, or other geometric elements,
wherein the anchor points correspond to coordinates plottable on an X-Y grid for the base sloper or coordinates plottable on an X-Y-Z grid for the base 3D object template;
displaying conditions in the patternmaking application relating to design details or changes to accommodate unique proportions of the clothing article or of the 3D object, wherein the conditions are displayed as “if/then” statements having true or false fields, and wherein the patternmaking application analyzes the measurements and changes an arrangement of one or more of the anchor points or the connecting elements of the base sloper or of the base 3D object template if a condition is met as true or false;
receiving user selections for implementing the conditions from among a first option to apply default design details or changes, a second option to apply different design details or changes, and a third option to apply new conditions with new design details or changes;
updating the conditions according to the user selections;
analyzing, using the patternmaking application, the measurements and the updated conditions and modifying the base sloper or the base 3D object template if needed to produce a final sloper corresponding to the digital sewing pattern or a final 3D object template corresponding to the digital 3D object pattern;
displaying the digital sewing pattern or the 3D digital object pattern in the patternmaking application;
receiving new measurements relating to the clothing article or relating to the 3D object in the patternmaking application;
analyzing, using the patternmaking application, the new measurements and the updated conditions and modifying the final sloper or the final 3D object template if needed to produce an updated digital sewing pattern or an updated 3D digital object pattern; and
displaying the updated digital sewing pattern or the updated 3D digital object pattern in the patternmaking application.

2. The computer implemented method of claim 1, further comprising:
configuring a machine learning trained module to identify errors in the user selections for implementing the conditions; and
applying new conditions with new design details or changes to the base sloper or to the base 3D object template based on any errors identified by the machine learning trained module.

3. The computer implemented method of claim 1, wherein receiving and storing measurements relating to the clothing article or relating to the 3D object further comprises:
determining whether there are empty measurement fields in the received measurements;
if there are empty measurement fields, calculating values for the empty measurement fields using built in mathematical equations included in the patternmaking application; and
if the values for the empty measurement fields cannot be calculated, asking for more data to be provided for the empty measurement fields.

4. The computer implemented method of claim 1, wherein
the measurements relating to the digital sewing pattern comprise data received from a body scanner and/or data obtained by manually measuring the clothing article;
the measurements relating to the 3D object comprise data received from a 3D object scanner and/or data obtained from manually measuring the 3D object.

5. The computer implemented method of claim 1, wherein
receiving the selection for the base sloper further comprises accessing a base sloper database comprising a plurality of base slopers relating to a plurality of clothing articles; and
receiving the selection for the base 3D object template further comprises accessing a 3D object template database comprising a plurality of base 3D object templates relating to a plurality of 3D objects.

6. The computer implemented method of claim 1, further comprising:
displaying the anchor points and the X-Y locations of the anchor points on the X-Y grid for the base sloper; and
displaying the anchor points and X-Y-Z locations of the anchor points on the X-Y-Z grid for the base 3D object template.

7. The computer implemented method of claim 6, further comprising:
displaying related measurements and any measurement actions and calculations used to create the X-Y locations of the anchor points for the base sloper; and
displaying related measurements and any measurement actions and calculations used to create the X-Y-Z locations of the anchor points for the base 3D object template.

8. A computer implemented method for producing a digital 3D object pattern usable to produce a 3D object, comprising:
receiving a request to open a file for the digital 3D object pattern in a patternmaking application;
receiving and storing measurements in the patternmaking application relating to the 3D object;
receiving a selection in the patternmaking application for a base 3D object template;
displaying the base 3D object template in the patternmaking application, wherein the base 3D object template comprises anchor points connected by connecting elements including lines, curves, or other geometric elements,
wherein the anchor points correspond to coordinates plottable on an X-Y-Z grid;
displaying conditions in the patternmaking application relating to design details or changes to accommodate unique proportions of the 3D object, wherein the conditions are displayed as “if/then” statements having true or false fields, and wherein the patternmaking application analyzes the measurements and changes an arrangement of one or more of the anchor points or the connecting elements of the base 3D object template if a condition is met as true or false;
receiving user selections for implementing the conditions from among a first option to apply default design details or changes, a second option to apply different design details or changes, and a third option to apply new conditions with new design details or changes;
updating the conditions according to the user selections;
analyzing, using the patternmaking application, the measurements and the updated conditions and modifying the base 3D object template if needed to produce a finalized 3D object template corresponding to the digital 3D object pattern;
displaying the 3D digital object pattern in the patternmaking application;
receiving new measurements relating to the 3D object in the patternmaking application;
analyzing, using the patternmaking application, the new measurements and the updated conditions and modifying the finalized 3D object template if needed to produce an updated 3D digital object pattern; and
displaying the updated 3D digital object pattern in the patternmaking application.

9. The computer implemented method of claim 8, further comprising:
configuring a machine learning trained module to identify errors in the user selections for implementing the conditions; and
applying new conditions with new design details or changes to the base 3D object template based on any errors identified by the machine learning trained module.

10. The computer implemented method of claim 8, wherein receiving and storing measurements relating to the 3D object further comprises:
determining whether there are empty measurement fields in the received measurements;
if there are empty measurement fields, calculating values for the empty measurement fields using built in mathematical equations included in the patternmaking application; and
if the values for the empty measurement fields cannot be calculated, asking for more data to be provided for the empty measurement fields.

11. The computer implemented method of claim 8, wherein the measurements relating to the 3D object comprise data received from a 3D object scanner and/or data obtained from manually measuring the 3D object.

12. The computer implemented method of claim 8, wherein receiving the selection for the base 3D object template further comprises accessing a 3D object template database comprising a plurality of base 3D object templates relating to a plurality of 3D objects.

13. The computer implemented method of claim 8, further comprising displaying the anchor points and X-Y-Z locations of the anchor points on the X-Y-Z grid for the base 3D object template.

14. The computer implemented method of claim 13, further comprising displaying related measurements and any measurement actions and calculations used to create the X-Y-Z locations of the anchor points for the base 3D object template.

15. A computer implemented method for producing a digital sewing pattern usable to produce a clothing article, comprising:
receiving a request to open a file for the digital sewing pattern in a patternmaking application;
receiving and storing measurements in the patternmaking application relating to the clothing article;
receiving a selection in the patternmaking application for a base sloper;
displaying the base sloper in the patternmaking application, wherein the base sloper comprises anchor points connected by connecting elements including lines, curves, or other geometric elements,
wherein the anchor points correspond to coordinates plottable on an X-Y grid;
displaying conditions in the patternmaking application relating to design details or changes to accommodate unique proportions of the clothing article, wherein the conditions are displayed as “if/then” statements having true or false fields, and wherein the patternmaking application analyzes the measurements and changes an arrangement of one or more of the anchor points or the connecting elements of the base sloper if a condition is met as true or false;
receiving user selections for implementing the conditions from among a first option to apply default design details or changes, a second option to apply different design details or changes, and a third option to apply new conditions with new design details or changes;
updating the conditions according to the user selections;
analyzing, using the patternmaking application, the measurements and the updated conditions and modifying the base sloper if needed to produce a final sloper corresponding to the digital sewing pattern;
displaying the digital sewing pattern in the patternmaking application;
receiving new measurements relating to the clothing article in the patternmaking application;
analyzing, using the patternmaking application, the new measurements and the updated conditions and modifying the final sloper if needed to produce an updated digital sewing pattern; and
displaying the updated digital sewing pattern in the patternmaking application.

16. The computer implemented method of claim 15, further comprising:
configuring a machine learning trained module to identify errors in the user selections for implementing the conditions; and
applying new conditions with new design details or changes to the base sloper based on any errors identified by the machine learning trained module.

17. The computer implemented method of claim 15, wherein receiving and storing measurements relating to the clothing article further comprises:
determining whether there are empty measurement fields in the received measurements;
if there are empty measurement fields, calculating values for the empty measurement fields using built in mathematical equations included in the patternmaking application; and
if the values for the empty measurement fields cannot be calculated, asking for more data to be provided for the empty measurement fields.

18. The computer implemented method of claim 15, wherein the measurements relating to the digital sewing pattern comprise data received from a body scanner and/or data obtained by manually measuring the clothing article.

19. The computer implemented method of claim 15, wherein receiving the selection for the base sloper further comprises accessing a base sloper database comprising a plurality of base slopers relating to a plurality of clothing articles.

20. The computer implemented method of claim 1, further comprising displaying the anchor points and the X-Y locations of the anchor points on the X-Y grid for the base sloper.
